(19) United States
(12) Patent Application Publication
(10) Pub. No.: US 2005/0191771 A1
(43) Pub. Date: Sep. 1, 2005

(54) Ultrafast laser direct writing method for modifying existing microstructures on a submicron scale

(76) Inventors: Ming Li, Chelsmford, MA (US); Makoto Ishizuka, Osaka (JP)

Correspondence Address: RATNERPRESTIA, P O BOX 980, VALLEY FORGE, PA, 19482-0980, US

(21) Appl. No.: 10/790,401

(22) Filed: Mar. 1, 2004

(51) Int. Cl. H01L 21/66

(52) U.S. Cl. 438/14

(57) ABSTRACT

A method for pre-calibration of a laser micro-machining system to achieve alignment tolerances greater than the diffraction limit of an illumination wavelength. A blank is mounted in the system, such that the beam spot is incident on its top surface. Two marks are ablated in the blank. The centers of the marks are a predetermined distance apart. The blank is illuminated with light and imaged with a digital camera. The resulting image is scaled such that each pixel has a width corresponding to a distance on the imaged surface, which is less than half of the illumination wavelength. The number of pixels between the centers of the marks determines this distance. The locations of the marks in the image are determined and a coordinate system is defined for surfaces imaged by the digital camera. Coordinates of the beam spot in this coordinate system are also determined using the second mark.

### FIELD OF THE INVENTION

The present invention concerns a simplified method for micro- and nano-machining of submicron features on existing microstructures. This method may also allow mass customization of generic electronic and mechanical microstructures.

### BACKGROUND OF THE INVENTION

As products get smaller and smaller, there is stronger and stronger demand for micro-electrical-mechanical systems (MEMS), micro-optical devices and photonic crystals. With this demand, there is an associated increased interest in micro- and nano-machining. There are numerous possible applications for MEMS. As a breakthrough technology, allowing unparalleled synergy between previously unrelated fields such as biology and microelectronics, many new MEMS applications have emerged and many more may emerge in the near future, expanding beyond those currently identified or known. Additional applications in quantum electric devices, micro-optical devices and photonic crystals are also emerging.

Here are a few applications of current interest:

Quantum Electrical Devices

Interest in ideas such as quantum computing have led to the development of devices requiring increasing smaller dimensions, such as cellular automata and coupled quantum dot technologies. Resonant tunneling devices such as resonant tunneling diodes, which may utilize quantum effects of transmission electrons to increase the efficiency of microwave circuits, require particularly fine features.

Micro-Optics

The application of micro-machining techniques to optics has lead to numerous advances in optical fabrication such as gray scale technology. Gray scale technology allows for the creation of a wide variety of shapes allowing for the best optical performance achievable. Traditional binary optics rely on a “stair step” shaped approximation of the ideal surface shape. Gray scale can actually create that ideal shape. Curves, ramps, torroids, or any other shape is possible. Multi-function optics, microlens arrays, diffusers, beam splitters, and laser diode correctors may all benefit from the use of gray scale technology. These optical devices as well as others, including fine pitch gratings for shorter and shorter wavelength light, benefit from increased precision due available using micro-machining. Optical MEMS devices including beam shapers, continuous membrane deformable mirrors, moving mirrors for tunable lasers, and scanning two axis tilt mirrors have also emerged due to progress in micro-machining technology.

Photonic Crystals

Photonic crystals represent an artificial form of optical material that may be used to create optical devices with unique properties. Photonic crystals have many optical properties that are analogous to the electrical properties of semiconductor crystals and, thus, may also allow the development of optical circuitry similar to present electrical semiconductor circuitry. The feature sizes used to form photonic crystals and the precise alignment requirements of these features complicate manufacture of these materials. Improved alignment techniques and reduced minimum feature size capabilities for micro-machining systems may lead to further developments in this area.

Biotechnology

MEMS technology has enabling new discoveries in science and engineering such as: polymerase chain reaction (PCR) microsystems for DNA amplification and identification; micro-machined scanning tunneling microscope (STM) probe tips; biochips for detection of hazardous chemical and biological agents; and microsystems for high-throughput drug screening and selection.

Communications

In addition to advances that may result from the use of resonant tunneling devices, high frequency circuits may benefit considerably from the advent of RF-MEMS technology. Electrical components such as inductors and tunable capacitors made using MEMS technology may perform significantly better than their present integrated circuit counterparts. With the integration of such components, the performance of communication circuits may be improved, while the total circuit area, power consumption and cost may be reduced. In addition, a MEMS mechanical switch, as developed by several research groups, may be a key component with huge potential in various microwave circuits. The demonstrated samples of MEMS mechanical switches have quality factors much higher than anything previously available. Reliability, precise tuning, and packaging of RF-MEMS components are to be critical issues that need to be solved before they receive wider acceptance by the market.

Advances in micro-optics and the introduction of new optical devices using photonic crystals may also benefit communications technology.

Accelerometers

MEMS accelerometers are quickly replacing conventional accelerometers for crash air-bag deployment systems in automobiles. The conventional approach uses several bulky accelerometers made of discrete components mounted in the front of the car with separate electronics near the air-bag. MEMS technology has made it possible to integrate the accelerometer and electronics onto a single silicon chip at a cost of ⅕ to 1/10 of the cost of the conventional approach. These MEMS accelerometers are much smaller, more functional, lighter, and more reliable as well, compared to the conventional macro-scale accelerometer elements.

Micro-Circuitry

Reducing the size of electronic circuits is another area in which MEMS technology may affect many fields. As the density of components and connections increases in these microcircuits, the processing tolerances decrease. One challenge in producing micro-circuitry is preventing shorts between components and nano-wires which are located ever closer together. Yields may be significantly increased by micromachining methods with the capability to repair these defects.

This illustrates one particular challenge in micro-machining, how to modify existing micro- or nano-structures (i.e. where the work piece already has complicated microstructures). Micromachining of submicron features has been a domain predominated by electron-beam, ultraviolet beam, and X-ray lithographic machines, as well as focused ion beam machines. These high-cost techniques usually require stringent environmental conditions, such as high vacuum or clean room condition. All the lithographic methods require a series of complicated procedures, which involve generating multiple masks and using photoresist. If a beam processing technique is used, this process requires the beam to be directed accurately at the desired location with a high degree of precision for proper processing. Only four currently available technologies (laser direct writing, focused ion beam writing, micro electric discharge machine, and photochemical etching) have this potential capability. Other techniques (for example ion beam milling) are only desirable for flat wafer processing. However, direct laser writing has additional advantages including: (1) operation in ambient air under optical illumination; (2) the capability of forming structures inside transparent materials; and (3) low materials dependence.

The emergence of ultrafast lasers makes submicron-level direct writing possible. In late 1999 and early 2000, the capability of femtosecond laser with a UV wavelength of 387 nm to machine ˜200 nm air holes with pitch size of ˜420 nm in plain Si-on-SiO₂ substrate was demonstrated. This demonstration met both the feature size (<200 nm) and pitch size (<420 nm) requirements for a 1D waveguide photonic crystal. The next step was to study drilling small holes on narrow waveguides to make a 1D photonic crystal. Ultrafast lasers have proven to be very versatile tools for micro-, nano-machining. Feature sizes as small as ˜100 nm have now been demonstrated using ultrafast laser beam machining. Still alignment of a laser beam to nanostructures on existing microstructures is a difficult issue.

### SUMMARY OF THE INVENTION

An exemplary embodiment of the present invention is a method for manufacturing a quantum electronic device, which includes at least one fine feature on a submicron feature. The fine feature is located on the submicron feature with a tolerance of less than the illumination wavelength of light used to image the device during manufacture. A quantum electronic device preform including the submicron feature on its top surface is provided. The top surface of the quantum electronic device preform is illuminated with light having the illumination wavelength and imaged with a digital camera. This produces an alignment image of the top surface which includes a matrix of pixels. The alignment image is scaled such that each pixel has a width corresponding to a constant distance on the top surface of the quantum electronic device preform, which is less than half of the illumination wavelength. An image coordinate system is defined for the top surface of the quantum electronic device preform using the alignment image and the constant distance. Coordinates of a reference point and an orientation of the submicron feature are determined in the image coordinate system using the alignment image. Also, initial coordinates of the beam spot of the micro-machining laser in the image coordinate system are determined using the alignment image. The beam spot of the micro-machining laser is then aligned over a portion of the submicron feature of the quantum electronic device preform using the coordinates of the reference point and the orientation of the submicron feature, as well as the initial coordinates of the beam spot. Device material of the quantum electronic device preform is machined with the micro-machining laser to form the fine feature(s) on the submicron feature, completing the quantum electronic device.

Another exemplary embodiment of the present invention is a method for manufacturing a micro-optical device, which includes at least one fine feature on a submicron feature. The fine feature is located on the submicron feature with a tolerance of less than the illumination wavelength of light used to image the device during manufacture. A micro-optical device preform including the submicron feature on its top surface is provided. The top surface of the micro-optical device preform is illuminated with light having the illumination wavelength and imaged with a digital camera. This produces an alignment image of the top surface which includes a matrix of pixels. The alignment image is scaled such that each pixel has a width corresponding to a constant distance on the top surface of the micro-optical device preform, which is less than half of the illumination wavelength. An image coordinate system is defined for the top surface of the micro-optical device preform using the alignment image and the constant distance. Coordinates of a reference point and an orientation of the submicron feature are determined in the image coordinate system using the alignment image. Also, initial coordinates of the beam spot of the micro-machining laser in the image coordinate system are determined using the alignment image. The beam spot of the micro-machining laser is then aligned over a portion of the submicron feature of the micro-optical device preform using the coordinates of the reference point and the orientation of the submicron feature, as well as the initial coordinates of the beam spot. Device material of the micro-optical device preform is machined with the micro-machining laser to form the fine feature(s) on the submicron feature, completing the micro-optical device.

An additional exemplary embodiment of the present invention is a method for manufacturing a micro-mechanical oscillator, which includes at least one fine feature on a submicron feature. The fine feature is located on the submicron feature with a tolerance of less than the illumination wavelength of light used to image the device during manufacture. A micro-mechanical oscillator preform including the submicron feature on its top surface is provided. The top surface of the micro-mechanical oscillator preform is illuminated with light having the illumination wavelength and imaged with a digital camera. This produces an alignment image of the top surface which includes a matrix of pixels. The alignment image is scaled such that each pixel has a width corresponding to a constant distance on the top surface of the micro-mechanical oscillator preform, which is less than half of the illumination wavelength. An image coordinate system is defined for the top surface of the micro-mechanical oscillator preform using the alignment image and the constant distance. Coordinates of a reference point and an orientation of the submicron feature are determined in the image coordinate system using the alignment image. Also, initial coordinates of the beam spot of the micro-machining laser in the image coordinate system are determined using the alignment image. The beam spot of the micro-machining laser is then aligned over a portion of the submicron feature of the micro-mechanical oscillator preform using the coordinates of the reference point and the orientation of the submicron feature, as well as the initial coordinates of the beam spot. Device material of the micro-mechanical oscillator preform is machined with the micro-machining laser to form the fine feature(s) on the submicron feature, completing the micro-mechanical oscillator.

A further exemplary embodiment of the present invention is a method for manufacturing a mold for microstructures, which includes at least one fine feature on a submicron feature. The fine feature is located on the submicron feature with a tolerance of less than the illumination wavelength of light used to image the mold during manufacture. A mold preform including the submicron feature on its top surface is provided. The top surface of the mold preform is illuminated with light having the illumination wavelength and imaged with a digital camera. This produces an alignment image of the top surface which includes a matrix of pixels. The alignment image is scaled such that each pixel has a width corresponding to a constant distance on the top surface of the mold preform, which is less than half of the illumination wavelength. An image coordinate system is defined for the top surface of the mold preform using the alignment image and the constant distance. Coordinates of a reference point and an orientation of the submicron feature are determined in the image coordinate system using the alignment image. Also, initial coordinates of the beam spot of the micro-machining laser in the image coordinate system are determined using the alignment image. The beam spot of the micro-machining laser is then aligned over a portion of the submicron feature of the mold preform using the coordinates of the reference point and the orientation of the submicron feature, as well as the initial coordinates of the beam spot. Mold material of the mold preform is machined with the micro-machining laser to form the fine feature(s) on the submicron feature, completing the mold for microstructures.

Yet another exemplary embodiment of the present invention is a method for forming a defect in a photonic crystal. A photonic crystal work piece is provided. The top surface of the photonic crystal work piece includes an alignment section and a photonic crystal section. The photonic crystal section has a number of air holes formed in an interstitial material. Each of the air holes has a diameter less than an illumination wavelength used to image the device during defect formation and the centers of two of the air holes are a predetermined distance apart. An origin mark is ablated in the alignment section of the photonic crystal work piece with a micro-machining laser. The top surface of the photonic crystal work piece is illuminated with light having the illumination wavelength and imaged with a digital camera. This produces an alignment image of the top surface which includes a matrix of pixels. The alignment image is scaled such that each pixel has a width corresponding to a constant distance on the top surface of the photonic crystal work piece, which is less than half of the illumination wavelength. The constant distance is determined based on a number of pixels in the alignment image between the centers of the two air holes that are separated by the predetermined distance. The location of the center of the calibration mark in the alignment image is determined and an image coordinate system for the top surface of the photonic crystal work piece is defined using the location of the origin mark in the alignment image, the matrix of pixels, and the constant distance. Coordinates of the centers of the air holes of the photonic crystal work piece in the image coordinate system are determined using the alignment image. Also, initial coordinates of the beam spot of the micro-machining laser in the image coordinate system are determined using the location of the origin mark in the alignment image. The beam spot of the micro-machining laser is then aligned over a defect location of the photonic crystal section using the coordinates of the air holes and the initial coordinates of the beam spot. Interstitial material at the defect location of the photonic crystal section is machined with the micro-machining laser to form the defect. A still further exemplary embodiment of the present invention is a method for improving

Yet a further exemplary embodiment of the present invention is a method for mass customizing microstructures with a laser micro-machining system, such that each customized microstructure has at least one of a set of customization features. A number of microstructure preforms provided. Each of these microstructure preform includes a submicron feature on its top surface. One microstructure preform is selected from among the provided microstructure preforms and at least one of the customization features is selected for the microstructure preform. The selected customization feature is to be located on the submicron feature with a tolerance less than an illumination wavelength used to image the microstructures during customization. The selected microstructure preform is coarsely aligned in the laser micro-machining system. The top surface of the selected microstructure preform is illuminated with light having the illumination wavelength and imaged with a digital camera. This produces an alignment image of the top surface which includes a matrix of pixels. The alignment image is scaled such that each pixel has a width corresponding to a constant distance on the top surface of the selected microstructure preform, which is less than half of the illumination wavelength. An image coordinate system is defined for the top surface of the selected microstructure preform using the alignment image and the constant distance. Coordinates of a reference point and an orientation of the submicron feature are determined in the image coordinate system using the alignment image. Also, initial coordinates of the beam spot of the micro-machining laser in the image coordinate system are determined using the alignment image. The beam spot of the micro-machining laser is then aligned over a portion of the submicron feature of the selected microstructure preform using the coordinates of the reference point and the orientation of the submicron feature, as well as the initial coordinates of the beam spot and the selected customization feature(s). Device material of the selected microstructure preform is machined with the micro-machining laser to form the customization feature(s) on the submicron feature of the selected microstructure preform to form a customized microstructure. This procedure is repeated for each of the microstructure preforms provided.

Yet an additional exemplary embodiment of the present invention is a method for repairing a microstructure, which includes a submicron defect on a top surface, with a laser micro-machining system. Machining of the submicron defect is performed with an accuracy of less than an illumination wavelength used to image the microstructure during repair. The defective microstructure is coupled to a repair mount, which includes an alignment surface adjacent to the defective microstructure. The repair mount is coarsely aligned in the laser micro-machining system, such that a beam spot of a micro-machining laser is incident on its alignment surface. A calibration mark is then ablated in the alignment surface of repair mount with the micro-machining laser. The top surface of the defective microstructure and the alignment surface of the repair mount are illuminated with light having the illumination wavelength and imaged with a digital camera. This produces an alignment image of these surfaces which includes a matrix of pixels. The alignment image is scaled such that each pixel has a width corresponding to a constant distance on the imaged surfaces, which is less than half of the illumination wavelength. The location of the center of the calibration mark in the alignment image is determined and an image coordinate system is then defined for the top surface of the selected microstructure preform using the alignment image, the location of the center of the calibration mark in the alignment image, and the constant distance. Coordinates of the submicron defect of the top surface of the defective microstructure are determined in the image coordinate system using the alignment image. Also, initial coordinates of the beam spot of the micro-machining laser in the image coordinate system are determined using the location of the center of the calibration mark in the alignment image. The beam spot of the micro-machining laser is then aligned over a portion of the submicron defect of the defective microstructure using the coordinates of the submicron defect and the initial coordinates of the beam spot. Device material of the defective microstructure is machined with the micro-machining laser to repair the submicron defect of the defective microstructure.

Still another exemplary embodiment of the present invention is a method for pre-calibration of a laser micro-machining system to achieve alignment tolerances greater than the diffraction limit of the illumination wavelength used during pre-calibration for machining of pre-existing microstructures which include at least one submicron feature. An alignment blank is mounted in the laser micro-machining system, such that the beam spot of the micro-machining laser of the laser micro-machining system is incident on the top surface of the alignment blank. A first calibration mark and a second calibration mark are ablated in the top surface of the alignment blank with the micro-machining laser. The two calibration marks are located such that their centers are a predetermined distance apart. The top surface of the alignment blank is illuminated with light having the illumination wavelength and imaged with a digital camera. This produces an alignment image of the top surface of the alignment blank which includes a matrix of pixels. The alignment image is scaled such that each pixel has a width corresponding to a constant distance on the imaged surface, which is less than half of the illumination wavelength. The constant distance is determined based on the number of pixels between the centers of the two calibration marks in the alignment image. The locations of the centers of the two calibration marks in the alignment image are determined and an image coordinate system is then defined for surfaces imaged by the digital camera using the locations of the centers of the two calibration marks in the alignment image and the constant distance. The initial coordinates of the beam spot of the micro-machining laser in the image coordinate system are determined using the location of the center of the second calibration mark in the alignment image and the image coordinate system. The alignment blank is then removed from the laser micro-machining system and one of the pre-existing microstructures to be machined is mounted in the laser micro-machining system, such that a beam spot of the micro-machining laser is incident on a machining surface of the one pre-existing microstructure.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawing are the following figures:

FIG. 1 is a block diagram of an exemplary laser micro-machining system according to the present invention.

FIG. 2 is a flow chart illustrating an exemplary method of pre-calibrating a laser micro-machining system according to the present invention.

FIG. 3A is a pixel image of exemplary calibration marks which have diameters less that the diffraction limit of the illuminating light.

FIG. 3B is a schematic representation of the exemplary calibration marks in FIG. 3A, illustrating part of the exemplary method of FIG. 2.

FIG. 4 is a flow chart illustrating an exemplary method of manufacturing a microstructure device according to the present invention.

FIG. 5A is a top plan drawing of an exemplary microstructure preform that may be used for manufacture according the exemplary method of FIG. 4.

FIG. 5B is a side plan drawing of the exemplary microstructure preform of FIG. 5A.

FIG. 5C is a side plan drawing of the exemplary microstructure preform of FIG. 5A following processing according the exemplary method of FIG. 4.

FIG. 6 a schematic representation of an exemplary laser beam of the exemplary laser micro-machining system of FIG. 1, illustrating a method of laser machining features smaller than the beam spot size.

FIG. 7 is a flow chart illustrating an exemplary method of forming a defect in a photonic crystal according to the present invention.

FIG. 8 is a flow chart illustrating an exemplary method of mass customizing microstructure devices according to the present invention.

FIG. 9 is a flow chart illustrating an exemplary method of repairing defective microstructure devices according to the present invention.

### DETAILED DESCRIPTION OF THE INVENTION

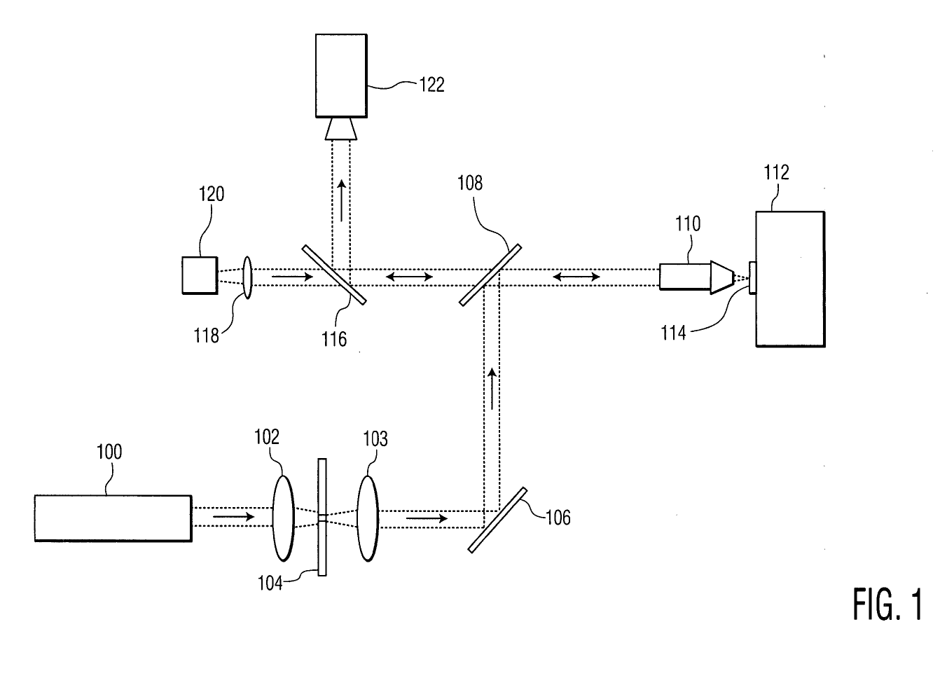

FIG. 1 illustrates a simplified block diagram of an exemplary laser micro-machining system that may be used in any of the exemplary methods of the present invention. This exemplary system includes laser source 100, work piece holder 112, work piece illumination source 120 and digital camera 122 to image the work piece, as well as numerous optical elements to direct and shape the optical beams. The optical beams are shown as dotted lines with arrows indicating the direction(s) of light propagating in the different sections of the exemplary system.

In this exemplary system, laser source 100 may desirably include an ultrafast laser, an excimer laser, or another type of laser typically used for laser machining applications. Harmonic generating crystals and/or amplifiers may be used within this component. Desirably, a frequency-doubled, 150 fs Ti:Sapphire laser (for example a Clark MXR CPA2000) may be used as the laser. Laser source 100 may also desirably include optics to control the intensity, polarization, and/or collimation of its laser beam output.

The output of laser source 100 may be desirably focused by lens 102 toward a pinhole in pinhole mask 104 and then re-collimated by lens 103. Passing the laser beam though pinhole mask 104 in this manner may desirably affect the beam shape of laser micro-machining beam. The laser beam is directed by dichroic mirror 106 and mirror 108 into microscope objective 110 which focuses the beam onto work piece 114, which is held in place by work piece holder 112. It is noted that microscope objective 110 may be replaced by separate optical elements, but this may complicate alignment of the system. Desirably, the laser beam is focused on the surface of the work piece in a diffraction limited, or nearly diffraction limited, spot to allow machining of a minimum feature size.

Work piece holder 112 may include, for example, a computer-controlled XYZ motion stage with micrometer resolution (for example, a micron resolution XYZ motion stage manufactured by Burleigh). A computer-controlled, piezo-electric XY motion stage with nanometer-resolution (for example, a piezo-electric XY motion stage manufactured by Queensgate) may also be included. Focusing of the laser beam may be achieved by moving work piece 114 nearer to or farther from microscope objective 110 using the XYZ motion stage. These one or two computer-controlled motion stages of work piece holder 112 may be used to align the beam spot of the laser micro-machining system on the surface of work piece 114, with the micrometer resolution XYZ motion stage providing coarse positioning and the piezo-electric motion stage providing fine positioning.

Alternatively, a computer-controlled, piezo-electric XY motion stage with nanometer-resolution (not shown) coupled to the pinhole mask may be used for fine alignment of the beam spot of the laser micro-machining system on work piece 114. As noted, the machining beam spot size on the surface of work piece 114 is desirably diffraction limited. The pinhole in pinhole mask 104 is desirably larger than this machining beam spot size. If the beam size at pinhole mask 114 is larger than the pinhole, moving the pinhole within the focused laser beam, may allow the beam spot formed on the surface of work piece 114 to be moved by a scaled amount, thereby increasing the ultimate precision of the beam spot alignment. This scaling is based on the ratio of the pinhole size to the machining spot size, which may desirably be 10:1 or greater. With a 10:1 ratio and using a computer-controlled, piezo-electric XY motion stage with nanometer-resolution to move the pinhole mask, the positioning of the machining beam spot may be controlled with an improved precision.

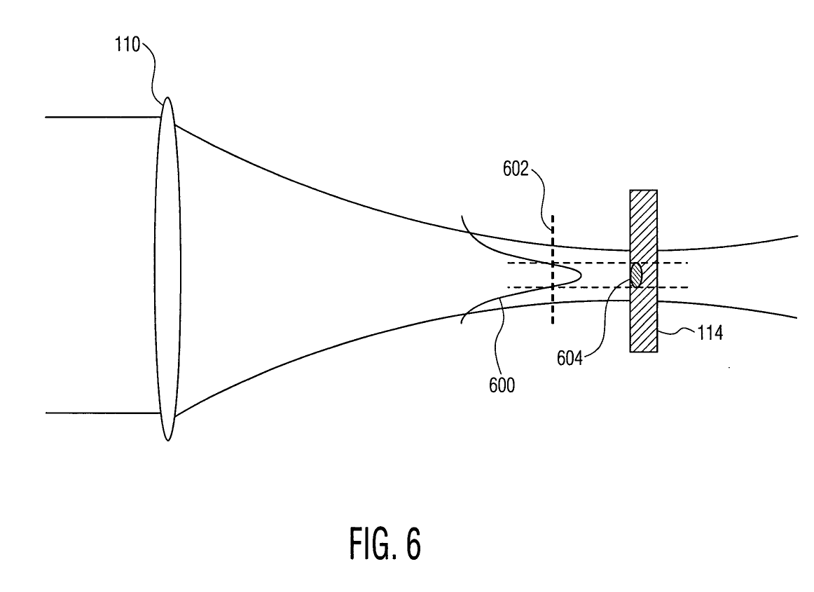

It is noted that the wavelength of the micro-machining laser included in the laser micro-machining system affects the minimum feature size that may machined with the system, but, in the case of an ultrafast micro-machining laser, it is possible to micro-machine fine features even smaller than the diffraction limited size of the beam spot. FIG. 6 illustrates a method by which this may be accomplished. In FIG. 6, the laser beam is focused into a diffraction limited beam spot on the top surface of work piece 114 by microscope objective 110 of an exemplary laser micro-machining system. Gaussian curve 600 represents the radial fluence of the laser beam on the surface. Line 602 is the machining threshold of the device material. Depending on the peak fluence of the laser beam, line 602 may fall above, below, or exactly at the full width at half maximum (FWHM) of Gaussian curve 602. The horizontal lines from the intersections of Gaussian curve 600 and line 602 define area 604 on the surface of work piece 114. Therefore, area 604 is the only portion of the surface to be machined directly by the laser. As shown in FIG. 6, this machined area may be significantly smaller than the spot size. Additional material may be machined due to conduction of thermal energy within the device material, but in laser machining with ultrafast lasers the heat affected zone formed in the material is minimized. Lowering the peak fluence, thus, may decrease the size of area 604, allowing the machining of fine features smaller that the diffraction limited spot size of the ultrafast laser.

To monitor the alignment of the laser micro-machining system and the progress of the processing, the surface of work piece 114 is illuminated by work piece illumination source 120 and imaged by digital camera 122 (for example, a Roper Scientific digital camera, having a matrix of 1300×1030 pixels, with a pixel length and width of ˜6.7 μm). The imaging light from the work piece illumination source is substantially collimated by lens 118 and passes through beam splitter 116 (possibly a half silvered mirror) and dichroic mirror 108, where it follows the path of the laser beam. These beams are focused onto work piece 114 by microscope objective 110. The imaging light is then reflected back through the microscope objective in the other direction. It passes back through dichroic mirror 108 and is reflected off beam splitter 116 into digital camera 122 to produce an image of the work piece surface. To reduce potential chromatic aberrations of this image, the imaging light desirably has a narrow spectrum. Thus, it may be desirable for work piece illumination source 120 to be a light emitting diode, a diode laser, or a filtered broad spectrum light source. Although the use of a dichroic mirror to combine the machining beam and the imaging beam makes is desirable for these light beams to have different wavelengths, it may also be desirable for the two light sources to have similar wavelengths so that the microscope objective may focus both beams similarly. Any difference between the focal lengths of the microscope objective at the illumination wavelength and the wavelength of the micro-machining laser may desirably be compensated by the optics of digital camera 122 and/or additional optics between beam splitter 116 and digital camera 112 (not shown).

As described above, it is desirable to be able to align the beam spot of the micro-machining laser with high accuracy. It has been demonstrated that ultrafast laser micro machining systems are capable of machining features smaller that their diffraction limited spot size. It also desirable to identify and machine features, which may have submicron dimension, on existing microstructures that may require an accuracy greater than the diffraction limited resolution of the exemplary imaging system of FIG. 1. Additionally, computer-controlled piezo-electric motion stages allow positioning accuracies, which exceed the diffraction limit of a visible light imaging system as shown in FIG. 1. A scanning electron microscope (SEM) may be used to monitor beam spot alignment for laser machining of submicron features on existing microstructures, however this is a much more expensive solution. Moreover, an SEM requires a vacuum system, which makes the drilling process significantly more complicated and less attractive. Additionally, an SEM is only practical for use with conductive materials or materials that may have a conductive coating applied.

The present invention includes methods by which the simpler exemplary imaging system of FIG. 1 may be operated beyond the diffraction limit to allow laser machining of submicron features on pre-existing microstructures. One exemplary embodiment of the present invention is a method for pre-calibrating an exemplary laser micro-machining system, such as shown in FIG. 1. Another is a method for the mass customization of microstructures using laser machining techniques. An additional exemplary embodiment of the present invention is the manufacture of microstructures using a laser machining step to form fine features on existing submicron features, which cannot be fully resolved by the optical alignment system. A further exemplary embodiment is the repair of defective microstructures by laser processing.

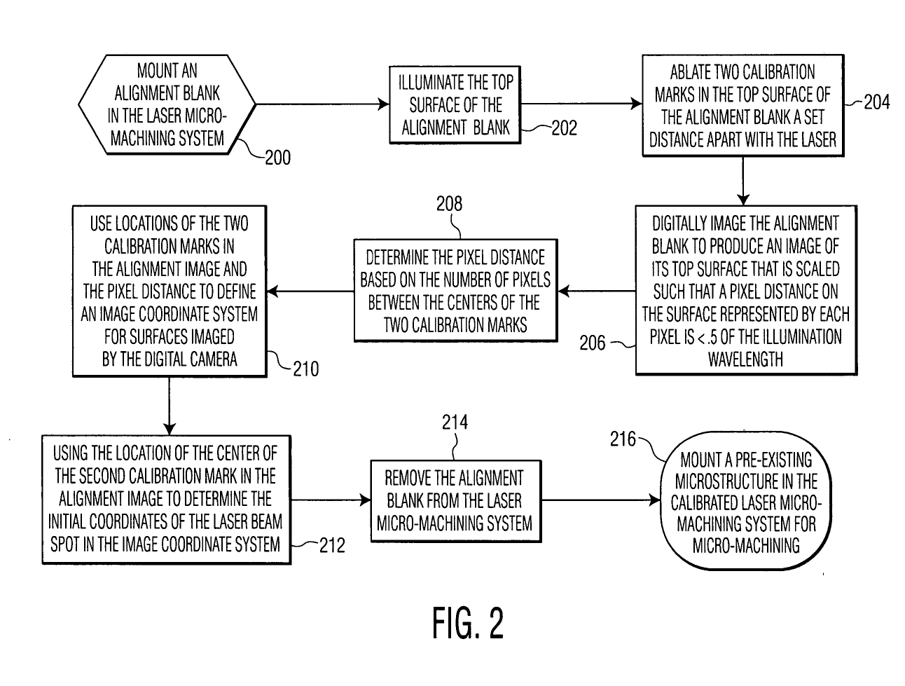

FIG. 2 illustrate an exemplary method for pre-calibration of a laser micro-machining system to achieve alignment tolerances greater than a diffraction limit of an illumination wavelength used during pre-calibration. This method may desirably allow for simplified laser machining of pre-existing microstructures, which include at least one submicron feature. Although the exemplary system of FIG. 1 is referenced to illustrate the exemplary methods of the present invention, this may be understood by one skilled in the art as illustrative of a laser micro-machining system the may be used in these methods and not as limiting.

An alignment blank (not shown) is mounted on work piece holder 112 of the exemplary laser micro-machining system, step 200, in the place of work piece 114. This alignment blank is small, flat piece of material that may be ablated by the laser micro-machining system to produce a calibration mark. The alignment blank is desirably mounted such that the beam spot of the micro-machining laser is incident on its top surface.

The top surface of the alignment blank is illuminated with light from illumination source 120, step 202, which desirably has a narrow bandwidth about a selected illumination wavelength. Two calibration marks are desirably ablated in the top surface of the alignment blank with the micro-machining laser, step 204. Although their exact locations may not be known when the calibration marks formed, these two calibration marks may be desirably located on the surface such that their centers are a predetermined distance apart. This may be accomplished to a high degree of precision using a computer-controlled piezo-electric motion stage to move work piece holder 112 or pinhole mask 104, as discussed above with reference to FIG. 1. It is noted that this separation distance may be measured in terms in standard units of distance, such as nanometers, or may be measured in terms of the voltage difference supplied to the piezo-electric motion stage or another arbitrary, but reproducible, unit.

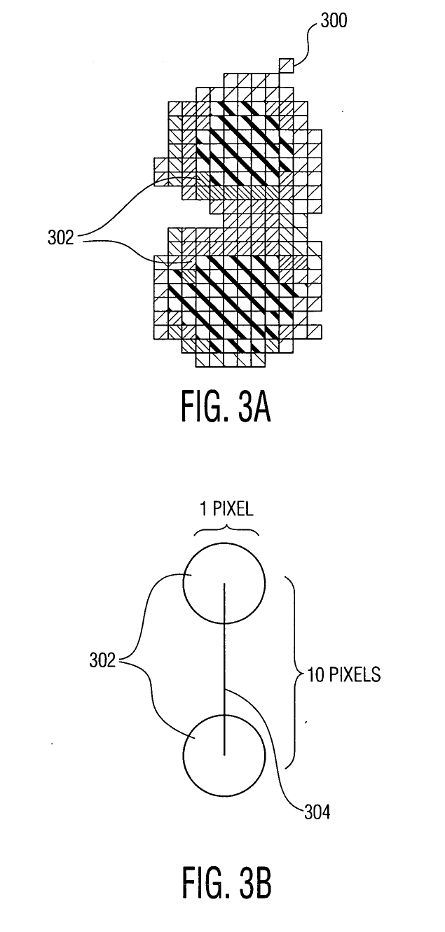

The top surface is imaged with digital camera 122, step 206, using this light to produce an alignment image of the top surface, showing the two calibration marks. As shown in FIG. 3A, the resulting alignment image 300 includes a matrix of pixels. In an exemplary monitoring setup, which produced alignment image 300 of FIG. 3A, microscope objective 110 and the “eyepiece” optics of digital camera 122 provide a magnification of ˜130. As the pixels of the exemplary digital camera measure ˜6.7 μm square, each pixel of this jitter-free digital camera corresponds to a ˜50 nm by ˜50 nm square on the alignment blank. However, since the illumination wavelength used in this example was ˜500 nm; anything smaller than 500 nm still remains irresolvable directly by any optical digital camera. It is well understood that any small feature with size comparable with the illumination wavelength is blurred according to point-spread-function and the beam aligning accuracy based on a single feature is still restricted by the diffraction limit of the wavelength. For discrete digital imagery, the blurry image x(n,m) is obtained from the object being imaged, s(n,m), by the convolution shown in equation (1)

$$x ( n , m ) = {\sum }_{a = - ∞}^{+ ∞} {\sum }_{b = - ∞}^{+ ∞} s ( n + a , m + b ) \cdot h ( - a , - b ) \qquad ( 1 )$$

where h(n,m) is the discrete point-spread-function for the imaging system. This applies to both calibration marks 302 in alignment image 300.

Individually, neither can be resolved optically. However, since both are blurred by the same imaging system, or h(n,m), and both features are geometrically symmetric (i.e. circular), the distance between the geometric centers of both objects is not blurred by the system. Thus, even though calibration marks 302 are only blurs in alignment image 300, the resolution problem may be overcome, shown schematically in FIG. 3B. This illustrates that even when the alignment image is scaled such that a width of each pixel corresponds to a constant distance on the imaged surface less than half of the illumination wavelength, or in exemplary image 300 ˜ 1/10 of the illumination wavelength, the locations of calibration holes 302 may be determined.

The constant distance may be determined based on a number of pixels between the centers of the two calibration marks 302 in the alignment image, step 208. Line 304 in FIG. 3B connects the centers of alignment marks 302. Counting the pixels between the centers in this exemplary alignment image gives a separation of 10 pixels vertically and 1 pixel horizontally. Dividing the number of pixels into the separation distance between the centers of the calibration marks gives a constant distance in the units used for the separation distance. It is noted that a greater number of calibration marks may be ablated and the constant distances calculated using different pairs of the calibration marks averaged to reduce uncertainty in this quantity.

Alternatively, the constant distance may be known, as in the example shown in FIG. 3A in which the constant distance is ˜50 nm. In this case, the known constant distance may be used to determine the scaling for the piezo-electric motion stage, thus the voltage difference used to move the beam spot between ablation of the first and the second calibration marks would equal ˜500 nm of movement.

Thus, the alignment accuracy is no longer limited by the illumination wavelength. The resolution of digital CCD camera 122 becomes the limiting factor for measurement precision. In the worst scenario, the exemplary alignment measurement shown in FIG. 3A is off by one pixel for each calibration mark. If these errors are in opposite directions, then the maximum error is 2 pixels, or ˜100 nm in absolute scale. However, the mean error, representing the most likely case, is just 1 pixel, or ˜50 nm in absolute scale. This prediction has been verified experimentally, and a mean positioning error<50 nm achieved. This allows an accuracy to be achieved of about 1/10 of the illumination light wavelength.

Using locations of the two calibration marks in the alignment image as reference points and the constant distance for scale, an image coordinate system for surfaces imaged by the digital camera may be defined, step 210.

Also of importance for aligning the laser micro-machining system to machine pre-existing microstructures is knowing the location at which machining may be expected to occur within this image. The location of the center of the second calibration in the alignment image provides this information. Using the location of the center of the second calibration mark in the alignment image and the image coordinate system allows the initial coordinates of the beam spot in the image coordinate system to be determined, step 212, when the micro-machining process begins. Unless the beam spot is intentionally moved or the system is perturbed the location of the beam spot is kept constant at the location of the last operation (in this case ablating the second calibration mark). The laser micro-machining system is now pre-calibrated. The alignment blank may be removed from the laser micro-machining system, step 214, and a pre-existing microstructure, or other work piece, may be mounted on work piece holder 112 in its place for machining, step 216.

Quantum cellular automata, coupled quantum dot devices, resonant tunneling devices, multifunction optical arrays, diffractive optical elements, beam shapers, microlens arrays, optical diffusers, beam splitters, laser diode correctors, fine pitch gratings, photonic crystals, micro-electrical-mechanical systems, micro-circuitry, micro-surface-acoustic-wave devices, and micro-mechanical oscillators, polymerase chain reaction microsystems, biochips for detection of hazardous chemical and biological agents, high-throughput drug screening and selection Microsystems, and molds to form other microstructures are examples of microstructures that may be machined by an exemplary laser micro-machining system pre-calibrated according to this exemplary method. These microstructures may be manufactured, repaired, or customized using the calibrated laser micro-machining system.

It may be possible to machine a number of work pieces without recalibration, or this pre-calibration procedure may be performed before machining of each piece depending on the drift and/or hysteresis of the system.

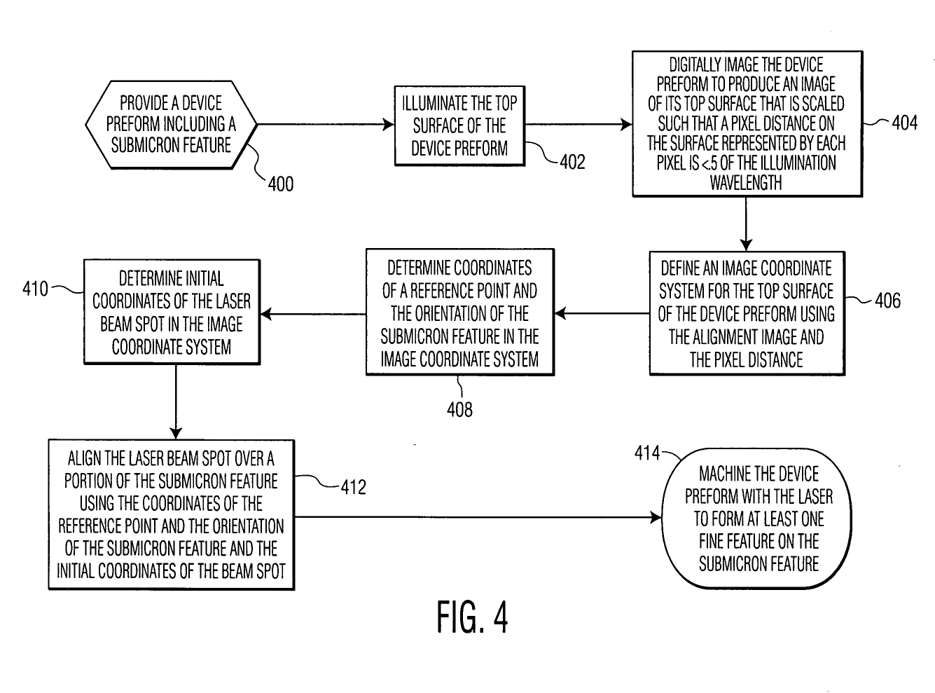

FIG. 4 illustrates an exemplary method for manufacturing a microstructure device, which involves adding at least one fine feature on a submicron feature of a device preform, which has already been machined to form this “coarse” submicron feature. This pre-machining of the device preform may be accomplished using any micro-machining technique, including laser machining. It is noted that the exemplary device preforms of the microstructures to be manufactured may include only a single microstructure or may be as large as a production wafer, including hundreds or thousands of individual microstructures.

Possible microstructure devices that may be manufactured using this method include quantum electronic devices, micro-optical devices, MEMS devices such as micro-mechanical oscillators, photonic crystals, and molds to mass produce microstructures. Microstructures which may be formed using such molds include quantum cellular automata, coupled quantum dot devices, resonant tunneling devices, multifunction optical arrays, diffractive optical elements, beam shapers, microlens arrays, optical diffusers, beam splitters, laser diode correctors, fine pitch gratings, photonic crystals, micro-electrical-mechanical systems, micro-circuitry, polymerase chain reaction microsystems, biochips for detection of hazardous chemical and biological agents, high-throughput drug screening and selection microsystems, micro-surface-acoustic-wave devices, and micro-mechanical oscillators. It is noted that in the present disclosure micro-optical devices are defined as discrete optical devices or arrays of optical devices formed from optical material. Photonic crystals are defined as a type of optical material and are not defined as micro-optical devices themselves, although an optical device could be formed from photonic crystal material.

As shown in FIG. 4, the device preform is provided, step 400, and its top surface is illuminated with light having an illumination wavelength, step 402. As described above with reference to the method of FIG. 2, it is desirable that the illumination light have a narrow bandwidth to improve imaging.

The top surface of the device preform is then imaged with a digital camera to produce a matrix of pixels, which form the alignment image of the top surface, step 404. The alignment image is desirably scaled such that the width of each pixel corresponds to a constant distance on the top surface of the device preform. This constant distance is desirably less than half of the illumination wavelength and may be 1/10 of the illumination wavelength or even less.

Although this scaling leads to a blurry alignment image in which the submicron feature cannot be resolved, as described by equation (1), it is still possible for an exemplary laser micro-machining system to achieve the desired alignment accuracy to machine fine featured on the submicron feature. As in the exemplary method of FIG. 2, an image coordinate system for the top surface of the device preform is defined using this alignment image and constant distance, step 406. A number of methods may be used to define this image coordinate system, including pre-calibration of the laser micro-machining system according to the method of FIG. 2. If the constant distance is known, an arbitrary origin point may be selected and the matrix of pixel elements used to determine the x and y axes. Reference marks on the device preform may be used to define the image coordinate system by allowing the constant distance to be calculated in the same manner as may be done using calibration marks in the exemplary method of FIG. 2. These reference marks, which may also be integral parts of the microstructure or may be used for alignment purposes only, may be formed on the device preform before it is provided in step 400 and/or as part of the present exemplary method.

Once the image coordinate system is defined, the coordinates of a reference point on each submicron feature to be machined and the orientation of each feature within the image coordinate system are determined, step 408. If the submicron feature to be machined is symmetric, the center of the submicron feature may provide a convenient reference point. Also, the initial coordinates, in the image coordinate system, of the beam spot of the micro-machining laser on the top surface of the device preform, step 410. These coordinates and orientations may be desirably determined using the alignment image.

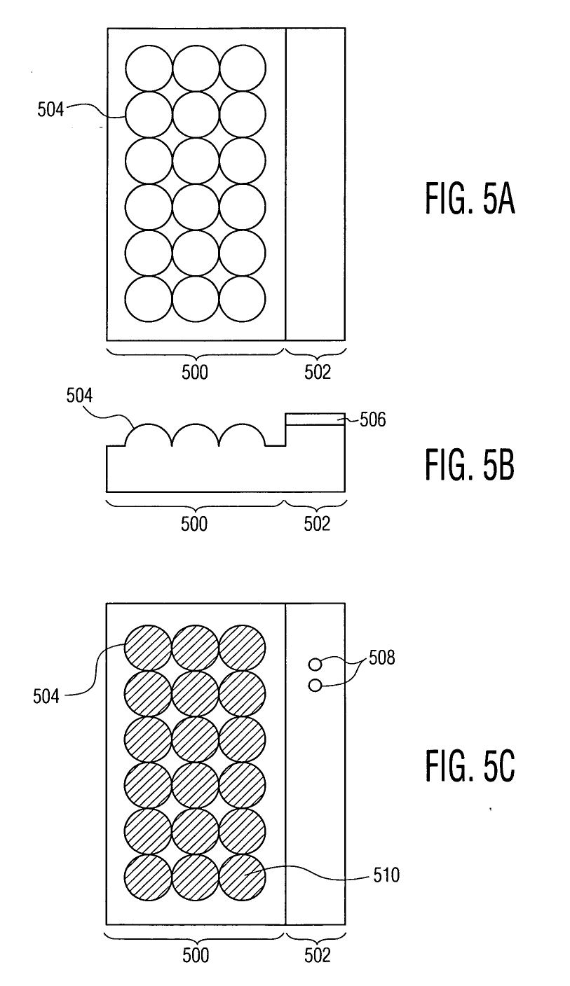

To assist with steps 406, 408, and, 410, the top surface of the device preform may be designed to include an alignment section into which one or more calibration marks may be ablated. Using this alternative design may prove advantageous over the exemplary method of FIG. 2 because the calibration and machining both occur with the device preform mounted in the work piece holder, but it requires the device preforms to include additional surface area without microstructures and may expose the microstructures to potential damage during calibration. FIGS. 5A and 5B illustrate top and side views, respectively, of an exemplary device preform, which includes both device section 500 and alignment section 502, that may be provided in step 400. The exemplary device preform shown is for an exemplary multi-function, micro-optical array. This exemplary multi-function, micro-optical array preform is merely illustrative of one possible device preform. Device section 500 includes microlenses 504, which are the submicron features of this exemplary device preform.

Initially, the beam spot of the micro-machining laser is coarsely aligned over alignment section 502. A few pulses from the micro-machining laser may then ablate a small calibration mark in the alignment section. Alignment section 502 may desirably include coating layer 506 as shown in FIG. 5B. This coating layer 506 may be formed of a material which has an ablation threshold that is lower than the machining threshold of the material of the top surface of device section 500. This allows the calibration marks to be ablated with a reduced fluence, thereby reducing the risk of damaging the microstructure device during calibration and alignment, even if the initial coarse alignment is wrong and the beam spot is mistakenly focused on device section 500 of the device preform instead of alignment section 502. Additionally, ablating calibration marks through coating layer 506 to reveal the material underneath may increase their contract and improve imaging of calibration marks 508. Easily ablated metals, such as gold, aluminum, and copper, may desirably be used to form coating layer 506 on device preforms formed of semiconductor material. Doping of the surface of the alignment section may also lower the ablation threshold of semiconductors. Polymers such as polyester, polyaniline, and polyimide may also be used to form coating layer 506.

Whether or not alignment section 502 is coated, the calibration mark ablated in the top surface of the device preform is substantially circular. Because the calibration mark is effectively symmetric, its center may be found in the alignment image and the corresponding coordinates determined. This provides a means to determine the initial coordinates of the beam spot of micro-machining laser in the image coordinate system for step 410.

Thus, if the constant distance is known, all of the information necessary to align the laser micro-machining system on a submicron feature of the device preform may be acquired by performing this first calibration. The constant distance may be known either: because it has been predetermined by the optical set up of the laser micro-machining system; or because the it has been calculated from the separations, in the alignment image, of the centers of one or more pair of reference marks on the device preform,

If the constant distance is not known and no convenient reference marks are available on the device preform, one or more additionally calibration marks may be formed in alignment section 502 of the device preform. The constant distance and image coordinate system may be determined from these multiple calibration marks in the same manner as in the exemplary method of FIG. 2. It is noted that the ablation of a second calibration mark in the alignment section may also be desirable to check the calibration of the beam spot positioning of the laser micro-machining system, even if the constant distance is already known.

Whichever exemplary method is used for their determination, once the initial coordinates of the beam spot of the micro-machining laser have been determined, the coordinates of each submicron feature of the device preform to be machined, and their orientations in the image coordinate system are determined, the beam spot may be aligned over a portion of the first submicron feature which is to be machined, step 412. As described above with reference the exemplary laser micro-machining system of FIG. 1, the location of the beam spot on the top surface of the device preform may be adjusted by moving either pinhole mask 104 or moving the device preform itself using work piece holder 112.

Device material of the device preform is machined with the micro-machining laser to form at least one fine feature on the submicron feature, step 414. These last two steps of alignment and machining are repeated for each desired submicron feature, desirably forming the completed microstructure device. FIG. 5C illustrates the exemplary device preform of FIGS. 5A and 5B, in which the microstructure (in this example, a multi-function, micro-optical array) has been completed according to the exemplary method of FIG. 4. In this exemplary microstructure, two calibration marks 508 have been ablated in alignment section 502 to assist in steps 406, 408, and 410, and fine pitch gratings 510 have been laser micro-machined on microlenses 504.

It is noted that machining the device material in step 414 may include either ablating the device material (i.e. altering the shape and/or size of the submicron feature) or permanently altering the structure of the device material in submicron feature. Examples of permanently altering the structure of the device material include: changing the index of refraction of the device material; altering the lattice structure of a crystalline device material, potentially forming an amorphous region within the crystal structure; and changing the chemical structure of the device material. Thus, the grating in the exemplary microstructure of FIG. 5C may be formed either by ablating grooves in the surface of microlenses 504 or by creating periodic changes in the index of refraction in the device material.

Another example of the exemplary method of FIG. 4 may be the machining of MEMS micro-mechanical oscillators to tune their resonance spectra. This exemplary method may include oscillating the micro-mechanical oscillators on the device preform before mounting it in the laser micro-machining system to determine the initial resonance spectra of the micro-mechanical oscillators. The initial resonance spectra may be compared to a desired resonance spectrum. The shape and location of the desired fine features to tune the resonance spectra may then be determined for machining in step 414.

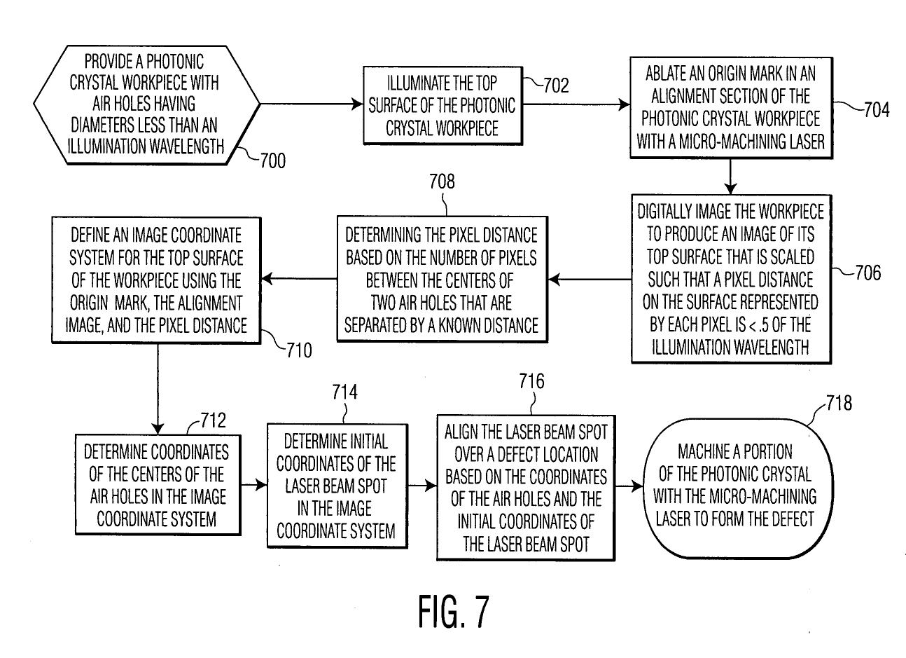

FIG. 7 illustrates another exemplary embodiment of the present invention, an exemplary method for forming a defect in a photonic crystal. It has been shown that it is possible to align an ultrafast laser beam to nanostructures on existing microstructures. Yet, machining defects on submicron-level waveguides, such as may be desirable for one dimensional photonic crystal materials, is more challenging than drilling substrates. It has been determined that narrower waveguides suffer a cracking problem during laser machining. The cracking probability is linked to the width of waveguide compared to the features formed in the waveguide. This cracking problem may be even worse for photonic crystal materials in which numerous air holes already exist, but adding defects to photonic crystal materials is desirable to affect their photonic bandgaps, in the same way that the doping of semiconductor materials may affect their electronic bandgaps. Machining such features requires highly accurate positioning (<100 nm) of the beam spot with respect to the waveguide.

In this exemplary method, as shown in FIG. 7, a photonic crystal work piece is provided, step 700, which includes an alignment section and a photonic crystal section. The photonic crystal section is formed by air holes drilled in an interstitial material. The centers of the air holes in the photonic crystal section are desirably arranged in a regular lattice pattern, such that the centers of pairs of air holes are a predetermined distance apart. The air holes in the photonic crystal section desirably have diameters and spacing on the order of the wavelength of the light with which the photonic crystal is designed to operate, or even smaller. These diameters and spacings may be less than the illumination wavelength which may be used to image the device during defect formation by an exemplary laser micro-machining system.

As in the preceding exemplary methods, the top surface of the photonic crystal work piece is illuminated with light having the illumination wavelength, step 702. An origin mark is ablated in the alignment section of the photonic crystal work piece with a micro-machining laser, step 704. As in the exemplary method of FIG. 4, the alignment section may include a coating layer to reduce the potential for damaging the interstitial material in the photonic crystal section of the work piece during this step. The top surface of the photonic crystal work piece is imaged with a digital camera to produce an alignment image, step 706.

The constant distance represented by each pixel in the alignment image is determined, step 708, based on the number of pixels in the alignment image between the centers of a pair of air holes that are separated by the predetermined distance. The image coordinate system is then defined for the top surface of the photonic crystal work piece, step 710, using a location of the origin mark in the alignment image, the matrix of pixels in the alignment image, and the constant distance determined in step 706.

The coordinates, in the image coordinate system, of the centers of the air holes in the photonic crystal section of the photonic crystal work piece may be determined, step 712, by locating them in the alignment image and the initial coordinates of a beam spot of the micro-machining laser in the image coordinate system may also be determined, step 714, using the location of the origin mark in the alignment image.

Using these coordinates of the air holes and the initial coordinates of the beam spot, the beam spot of the micro-machining laser is aligned over a desired defect location of the photonic crystal section, step 716, and the interstitial material at the desired defect location of the photonic crystal section is machined with the micro-machining laser, step 718, to form the defect. This machining of the interstitial material to form the defect may include ablating the interstitial material and/or permanently altering its refractive index.

As described above, the addition of defects into a photonic crystal material may function similarly to the doping of a semiconductor material. Additionally, the formation of defects in a photonic crystal material may allow tuning of its optical transmission spectrum. Similar to tuning of the resonance spectrum of a MEMS micro-mechanical oscillator, described above, the transmission spectrum of the, defect-free, photonic crystal may be determined and compared a desired transmission spectrum to determine the desired shape of the defect and the defect location to be formed in step 718. It is noted that the defect may be associated with an existing air hole, for example enlarging an air hole (or regular pattern of air holes). Alternatively, the defect may involve the addition of a new feature, for example the addition of interstitial air hole(s) or regions of interstitial material having a different refractive index.

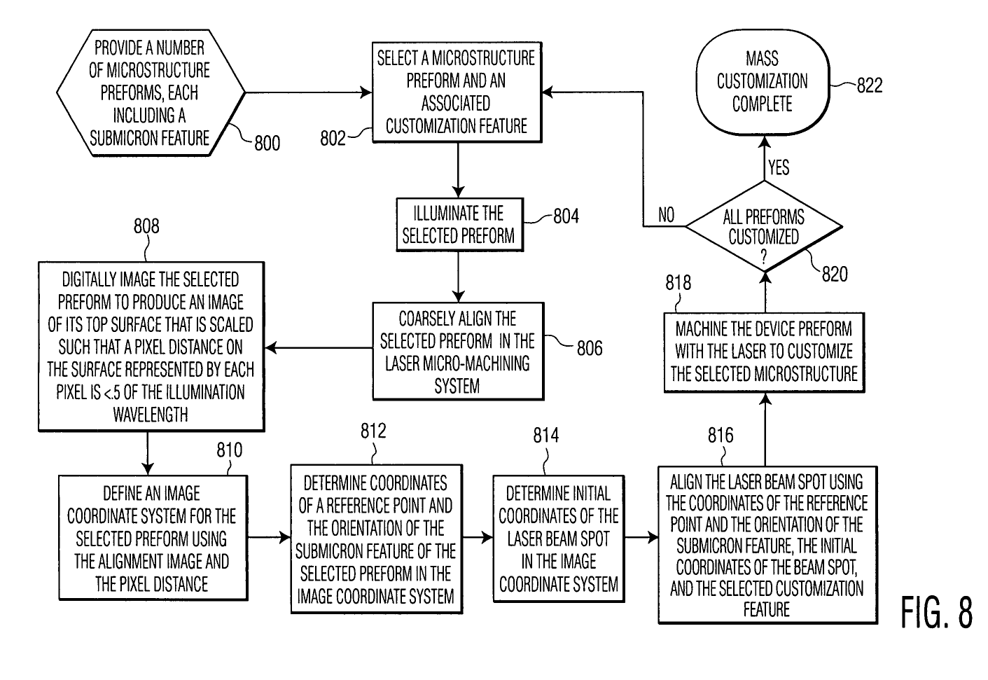

Another exemplary embodiment of the present invention, illustrated in FIG. 8, is a method for mass customizing a plurality of microstructures with a laser micro-machining system. Each of these microstructures has at least one customization features selected from a set of customization features added to it. These selected customization features may be located on one or more preexisting submicron feature with a tolerance less than the illumination wavelength used to image the microstructures during customization.

The term mass customization typically refers to the ability to mass produce products that have been individually customized to have different property or meet individualized specifications. For convenience, this narrow definition of mass customization of a microstructure is used herein. Thus, mass customized microstructures, according to the present invention, are microstructures in which fine features are added by laser machining to individual microstructure preforms which may be mass produced by preceding processing steps, allowing formation microstructures with different properties as desired. Manufacturing of microstructures according to the present invention, as described above with reference to FIG. 4, may or may not allow for the mass customization of the resulting microstructures.

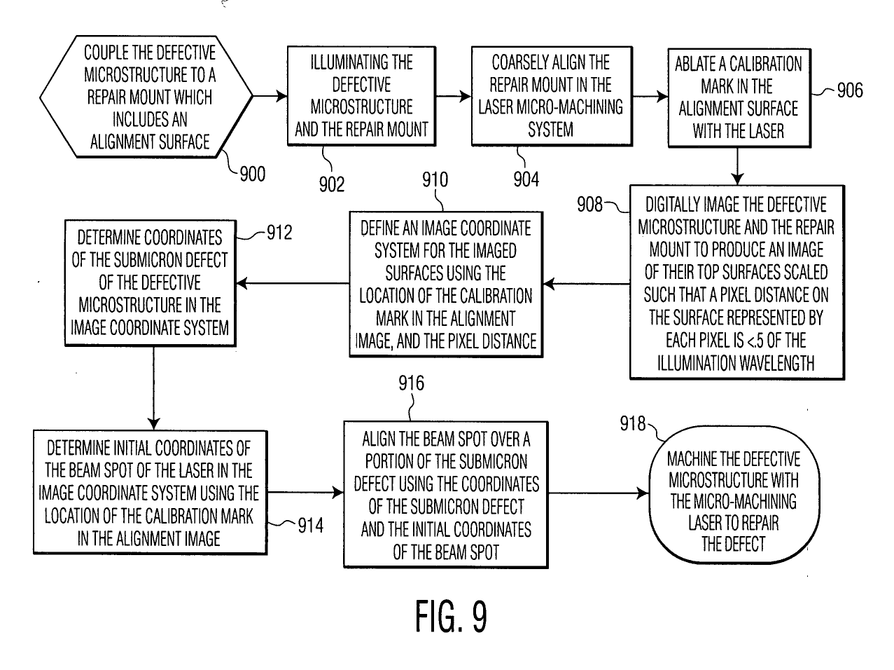

It is noted that the repair of defective microstructures as described below with reference to FIG. 9, may be conducted by processes similar to those of mass customization, but is conceptually different, requiring identification of the defect to be repaired prior to alignment and laser etching.

A number of microstructure preforms are provided, step 800, which desirably include a submicron feature on the top surface. From among these microstructure preforms, a single microstructure preform is selected, as well as at least one associated customization feature from the set of available customization features, step 802.

The selected microstructure preform is then illuminated with light having the illumination wavelength, step 804, coarsely aligned in the laser micro-machining system, step 806, and imaged with a digital camera to produce an alignment image of its top surface, step 808, as in the preceding exemplary method of FIGS. 2, 4, and 7. The alignment image is scaled such that a width of each pixel corresponds to a constant distance on the top surface of the selected microstructure preform less than half of the illumination wavelength.

An image coordinate system for the top surface of the selected microstructure preform is then defined, step 810, using the alignment image and the constant distance. The coordinates, in the image coordinate system, of a reference point and an orientation of submicron features of the selected microstructure preform on which the customization features are to be formed are determined, step 812, using the alignment image. The initial coordinates of the beam spot of the laser micro-machining system in the image coordinate system are also determined, step 814, using the alignment image. Steps 810, 812, and 814 may be performed using any of the methods described above with reference to FIG. 2, 4, or 7.

The beam spot of the laser micro-machining system is aligned over a desired portion of the selected microstructure preform, step 816, using the coordinates of the reference point and the orientation of the submicron feature determined in step 812, the initial coordinates of the beam spot determined in step 814, and the selected customization feature(s). The device material of the selected microstructure preform is machined with the laser micro-machining system to form the selected customization feature(s) on the submicron feature(s) of the selected microstructure preform, step 818, to form a customized microstructure.

It is then determined if any microstructure preforms remain to be customized, step 820. If any remain, another microstructure preform and its associated customization feature(s) are selected, step 802, and steps 804, 806, 808, 810, 812, 814, 816, 818, and 820 are repeated. If no microstructure preforms remain to be customized, then the mass customization of the microstructures is complete, step 822.

This exemplary method of mass customization may be applicable to microstructures including microstructure molds, quantum cellular automata, coupled quantum dot devices, resonant tunneling devices, multifunction optical arrays, diffractive optical elements, beam shapers, microlens arrays, optical diffusers, beam splitters, laser diode correctors, fine pitch gratings, photonic crystals, micro-electrical-mechanical systems, micro-circuitry, micro-surface-acoustic-wave devices, and micro-mechanical oscillators.

A further exemplary embodiment is a method for the repair of defective microstructures by laser processing. This exemplary method for repairing a microstructure with a laser micro-machining system is shown in FIG. 9. The microstructure to be repaired includes a submicron defect on its top surface. Repair of such a submicron defect may desirably require that the defect be located on the top surface of the microstructure with a tolerance less than the illumination wavelength of the laser micro-machining system used to image the microstructure during repair. This potential requirement may be met using one or more of the exemplary calibration and alignment methods described above with reference to FIGS. 2, 4, 7, and 8 as part of the exemplary method of FIG. 9.

The defective microstructure is desirably coupled to a repair mount, step 900, which may be held by work piece holder 112. This exemplary repair mount includes an alignment surface adjacent to the defective microstructure. The alignment surface may be desirably formed of a material which has an ablation threshold less than the machining threshold of the material of the defective microstructure. This easily ablated material of the alignment surface may be only a coating or may be used to form the bulk of the repair mount. As described above with reference to coating layer 506 in FIG. 5B, the use of a material with a low ablation threshold for the alignment surface may reduce the possibility of damaging the defective microstructure during alignment.

The top surface of the defective microstructure and the alignment surface of the repair mount are illuminated with light having an illumination wavelength, step 902. The repair mount, with the coupled defective microstructure, is coarsely aligned in the laser micro-machining system, step 904, such that a beam spot of the micro-machining laser is incident on the alignment surface of the repair mount. A calibration mark is then ablated in the alignment surface of the repair mount with the micro-machining laser, step 906, to identify the initial beam spot location of the laser micro-machining system.

The top surface of the defective microstructure and the alignment surface of the repair mount are imaged with a digital camera to produce an alignment image, step 908. As in the previous exemplary methods, the alignment image is scaled such that a width of each pixel corresponds to a constant distance on the imaged surfaces less than half of the illumination wavelength.

An image coordinate system is defined for the imaged surfaces, step 910, using this alignment image, the location of the center of the calibration mark in the alignment image, and the constant distance. The coordinates, in the image coordinate system, of the submicron defect of the defective microstructure are determined, step 912, using the alignment image. Using a location of the center of the calibration mark in the alignment image and the image coordinate system, the initial coordinates of the beam spot of the micro-machining laser in the image coordinate system are determined as well, step 914.

The beam spot of the laser micro-machining system is then aligned over a portion of the submicron defect, step 916, using the coordinates of the submicron defect determined in step 912 and the initial coordinates of the beam spot determined in step 914. The device material of the defective microstructure which formed the defect is machined with the laser micro-machining system, step 918, to repair the defective microstructure.

This exemplary repair method may desirably be used to repair many types of microstructures that may be rendered unusable due to a submicron defect. Micro-circuitry may be an area in which the exemplary repair method of FIG. 9 is of particular usefulness. As circuit density increases, production yields decreased due to short circuits between tightly packed conductors and circuit elements. Many of these short circuits may be identified as submicron defects in these micro-circuits. These defects may occur because of a submicron piece of metal or semiconductor that either was not fully etched or resulted from a submicron amount of excess growth during fabrication. Such defects may desirably be repaired by this exemplary method, thereby increasing yields significantly.

Other exemplary microstructures that may also be repaired using the exemplary method of FIG. 9 include: microstructure molds; quantum cellular automata; coupled quantum dot devices; resonant tunneling devices; multifunction optical arrays; diffractive optical elements; beam shapers; microlens arrays; optical diffusers; beam splitters; laser diode correctors; fine pitch gratings; photonic crystals; MEMS; micro-surface-acoustic-wave devices; micro-mechanical oscillators; polymerase chain reaction microsystems; biochips for detection of hazardous chemical and biological agents; and high-throughput drug screening and selection microsystems. Any of these microstructures may include a submicron defect formed similarly to the potential submicron short circuits that may occur in micro-circuitry.

The present invention includes a number of exemplary methods to easily calibrate and align a laser micro-machining system with a precision of less than the diffraction limit, using an optical system, and exemplary applications of these methods. The use of these exemplary methods allows greatly simplified, yet highly accurate, micro-machining in ambient atmosphere conditions. Such techniques may help to bring microstructures and nanotechnology into more common use. Although the invention is illustrated and described herein with reference to specific embodiments, the invention is not intended to be limited to the details shown. Rather, various modifications may be made in the details within the scope and range of equivalents of the claims and without departing from the invention.

1. A method for manufacturing a quantum electronic device, which includes at least one fine feature on a submicron feature, the at least one fine feature to be located on the submicron feature with a tolerance less than an illumination wavelength used to image the device during manufacture, the method comprising the steps of:
a) providing a quantum electronic device preform including the submicron feature on a top surface;
b) illuminating the top surface of the quantum electronic device preform with light having the illumination wavelength;
c) imaging the top surface of the quantum electronic device preform with a digital camera to produce an alignment image of the top surface which includes a matrix of pixels, the alignment image being scaled such that each pixel has a width corresponding to a constant distance on the top surface of the quantum electronic device preform, the constant distance being less than half of the illumination wavelength;
d) defining an image coordinate system for the top surface of the quantum electronic device preform using the alignment image and the constant distance;
e) determining coordinates of a reference point and an orientation of the submicron feature of the top surface of the quantum electronic device preform in the image coordinate system using the alignment image;
f) determining initial coordinates of a beam spot of a micro-machining laser in the image coordinate system using the alignment image;
g) aligning the beam spot of the micro-machining laser over a portion of the submicron feature of the quantum electronic device preform using the coordinates of the reference point and the orientation of the submicron feature determined in step (e) and the initial coordinates of the beam spot determined in step (f); and
h) machining device material of the quantum electronic device preform with the micro-machining laser to form the at least one fine feature on the submicron feature, completing the quantum electronic device.

2. The method according to claim 1, wherein the quantum electronic device is at least one of a quantum cellular automaton, a coupled quantum dot device, or a resonant tunneling device.

3. The method according to claim 1, wherein step (f) includes the steps of:
f1) ablating a calibration mark in an alignment section of the top surface of the quantum electronic device preform with the micro-machining laser; and
f2) determining a location of a center of the calibration mark in the alignment image;
f3) using the location of the center of the calibration mark in the alignment image and the image coordinate system defined in step (d) to determine the initial coordinates of the beam spot of the micro-machining laser in the image coordinate system.

4. The method according to claim 3, wherein step (d) includes the steps of:
d1) ablating a second calibration mark in the alignment section of the top surface of the quantum electronic device preform with the micro-machining laser, the second calibration mark located such that centers of the two calibration marks are a predetermined distance apart;
d2) determining the constant distance based on a number of pixels between the centers of the two calibration marks in the alignment image; and
d3) using locations of the two calibration marks in the alignment image and the constant distance determined in step (d2) to define the image coordinate system for the top surface of the quantum electronic device preform.

5. The method according to claim 3, wherein:
the constant distance is a predetermined distance; and
step (d) includes using the location of the center of the calibration mark in the alignment image, the matrix of pixels, and the constant distance to define the image coordinate system for the top surface of the quantum electronic device preform.

6. The method according to claim 3, wherein:
the quantum electronic device preform includes two reference marks, located such that the two reference marks have respective centers that are a predetermined distance apart; and
step (d) includes the steps of;
d1) determining the constant distance based on a number of pixels between the centers of the two reference marks in the alignment image; and
d2) using the location of the center of the calibration mark in the alignment image determined in step (f2) and the constant distance determined in step (d1) to define the image coordinate system for the top surface of the quantum electronic device preform.

7. The method according to claim 3, wherein:
the submicron feature of the quantum electronic device preform is formed of the device material, which has a device machining threshold;
the alignment section of the top surface of the quantum electronic device preform is coated with a coating material having a coating ablation threshold, the coating ablation threshold being less than the device machining threshold;
step (f1) includes operating the micro-machining laser with an alignment peak fluence to ablate the calibration mark in only the coating material of the alignment section, the alignment peak fluence being less than the device machining threshold and greater than the coating ablation threshold; and
step (h) includes operating the micro-machining laser with a machining peak fluence to machine the at least one fine feature in the device material of the submicron feature, the machining peak fluence being greater than the device machining threshold.

8. The method according to claim 1, wherein:
a light beam of the micro-machining laser propagates along a beam path including;
a transversely moveable pinhole mask having a pinhole located in the beam path; and
reducing optics to produce the beam spot on the top surface of the quantum electronic device preform having a beam spot diameter smaller than a pinhole diameter of the pinhole; and
step (g) includes aligning the beam spot of the micro-machining laser over the portion of the submicron feature of the quantum electronic device preform by moving the transversely moveable pinhole mask a scaled amount based on a ratio of the pinhole diameter to the beam spot diameter.

9. The method according to claim 1, wherein step (g) includes aligning the beam spot of the micro-machining laser over the portion of the submicron feature of the quantum electronic device preform by moving the quantum electronic device preform.

10. The method according to claim 1, wherein the micro-machining laser is one of an ultrafast laser or an excimer laser.

11. The method according to claim 1, wherein:
the micro-machining laser is an ultrafast laser;
a full width at half maximum (FWHM) of the beam spot of the micro-machining laser on the top surface is diffraction limited; and
step (h) includes operating the micro-machining laser with a machining fluence to machine the at least one fine feature in the device material of the submicron feature, the machining fluence being such that a diameter of an area of the top surface machined by a pulse of the ultrafast laser is less than the FWHM of the beam spot.

12. The method according to claim 1, wherein machining the device material in step (h) includes one of ablating the device material or permanently altering a structure of the device material.

13. A method for manufacturing a micro-optical device, which includes at least one fine feature on a submicron feature, the at least one fine feature to be located on the submicron feature with a tolerance less than an illumination wavelength used to image the device during manufacture, the method comprising the steps of:
a) providing a micro-optical device preform including the submicron feature on a top surface;
b) illuminating the top surface of the micro-optical device preform with light having the illumination wavelength;
c) imaging the top surface of the micro-optical device preform with a digital camera to produce an alignment image of the top surface which includes a matrix of pixels, the alignment image being scaled such that each pixel has a width corresponding to a constant distance on the top surface of the micro-optical device preform, the constant distance being less than half of the illumination wavelength;
d) defining an image coordinate system for the top surface of the micro-optical device preform using the alignment image and the constant distance;
e) determining coordinates of a reference point and an orientation of the submicron feature of the top surface of the micro-optical device preform in the image coordinate system using the alignment image;
f) determining initial coordinates of a beam spot of a micro-machining laser in the image coordinate system using the alignment image;
g) aligning the beam spot of the micro-machining laser over a portion of the submicron feature of the micro-optical device preform using the coordinates of the reference point and the orientation of the submicron feature determined in step (e) and the initial coordinates of the beam spot determined in step (f); and
h) machining device material of the micro-optical device preform with the micro-machining laser to form the at least one fine feature on the submicron feature, completing the micro-optical device.

14. The method according to claim 13, wherein the micro-optical device is at least one of a multifunction optical array, a diffractive optical element, or a beam shaper.

15. The method according to claim 13, wherein step (f) includes the steps of:
f1) ablating a calibration mark in an alignment section of the top surface of the micro-optical device preform with the micro-machining laser; and
f2) determining a location of a center of the calibration mark in the alignment image;
f3) using the location of the center of the calibration mark in the alignment image and the image coordinate system defined in step (d) to determine the initial coordinates of the beam spot of the micro-machining laser in the image coordinate system.

16. The method according to claim 15, wherein step (d) includes the steps of:
d1) ablating a second calibration mark in the alignment section of the top surface of the micro-optical device preform with the micro-machining laser, the second calibration mark located such that centers of the two calibration marks are a predetermined distance apart;
d2) determining the constant distance based on a number of pixels between the centers of the two calibration marks in the alignment image; and
d3) using locations of the two calibration marks in the alignment image and the constant distance determined in step (d2) to define the image coordinate system for the top surface of the micro-optical device preform.

17. The method according to claim 15, wherein:
the constant distance is a predetermined distance; and
step (d) includes using the location of the center of the calibration mark in the alignment image, the matrix of pixels, and the constant distance to define the image coordinate system for the top surface of the micro-optical device preform.

18. The method according to claim 15, wherein:
the micro-optical device preform includes two reference marks, located such that the two reference marks have respective centers that are a predetermined distance apart; and
step (d) includes the steps of;
d1) determining the constant distance based on a number of pixels between the centers of the two reference marks in the alignment image; and
d2) using the location of the center of the calibration mark in the alignment image determined in step (f2) and the constant distance determined in step (d1) to define the image coordinate system for the top surface of the micro-optical device preform.

19. The method according to claim 15, wherein:
the submicron feature of the micro-optical device preform is formed of the device material, which has a device machining threshold;
the alignment section of the top surface of the micro-optical device preform is coated with a coating material having a coating ablation threshold, the coating ablation threshold being less than the device machining threshold;
step (f1) includes operating the micro-machining laser with an alignment peak fluence to ablate the calibration mark in only the coating material of the alignment section, the alignment peak fluence being less than the device machining threshold and greater than the coating ablation threshold; and
step (h) includes operating the micro-machining laser with a machining peak fluence to machine the at least one fine feature in the device material of the submicron feature, the machining peak fluence being greater than the device machining threshold.

20. The method according to claim 13, wherein:
a light beam of the micro-machining laser propagates along a beam path including;
a transversely moveable pinhole mask having a pinhole located in the beam path; and
reducing optics to produce the beam spot on the top surface of the micro-optical device preform having a beam spot diameter smaller than a pinhole diameter of the pinhole; and
step (g) includes aligning the beam spot of the micro-machining laser over the portion of the submicron feature of the micro-optical device preform by moving the transversely moveable pinhole mask a scaled amount based on a ratio of the pinhole diameter to the beam spot diameter.

21. The method according to claim 13, wherein step (g) includes aligning the beam spot of the micro-machining laser over the portion of the submicron feature of the micro-optical device preform by moving the micro-optical device preform.

22. The method according to claim 13, wherein the micro-machining laser is one of an ultrafast laser or an excimer laser.

23. The method according to claim 13, wherein:
the micro-machining laser is an ultrafast laser;
a full width at half maximum (FWHM) of the beam spot of the micro-machining laser on the top surface is diffraction limited; and
step (h) includes operating the micro-machining laser with a machining fluence to machine the at least one fine feature in the device material of the submicron feature, the machining fluence being such that a diameter of an area of the top surface machined by a pulse of the ultrafast laser is less than the FWHM of the beam spot.

24. The method according to claim 13, wherein machining the device material in step (h) includes one of ablating the device material or permanently altering a structure of the device material.

25. A method for manufacturing a micro-mechanical oscillator, which includes at least one fine feature on a submicron feature, the at least one fine feature to be located on the submicron feature with a tolerance less than an illumination wavelength used to image the device during manufacture, the method comprising the steps of:
a) providing a micro-mechanical oscillator preform including the submicron feature on a top surface;
b) illuminating the top surface of the micro-mechanical oscillator preform with light having the illumination wavelength;
c) imaging the top surface of the micro-mechanical oscillator preform with a digital camera to produce an alignment image of the top surface which includes a matrix of pixels, the alignment image being scaled such that each pixel has a width corresponding to a constant distance on the top surface of the micro-mechanical oscillator preform, the constant distance being less than half of the illumination wavelength;
d) defining an image coordinate system for the top surface of the micro-mechanical oscillator preform using the alignment image and the constant distance;
e) determining coordinates of a reference point and an orientation of the submicron feature of the top surface of the micro-mechanical oscillator in the image coordinate system using the alignment image;
f) determining initial coordinates of a beam spot of a micro-machining laser in the image coordinate system using the alignment image;
g) aligning the beam spot of the micro-machining laser over a portion of the submicron feature of the micro-mechanical oscillator preform using the coordinates of the reference point and the orientation of the submicron feature determined in step (e) and the initial coordinates of the beam spot determined in step (f); and
h) machining device material of the micro-mechanical oscillator preform with the micro-machining laser to form the at least one fine feature on the submicron feature, completing the micro-mechanical oscillator.

26. The method according to claim 25, wherein step (f) includes the steps of:
f1) ablating a calibration mark in an alignment section of the top surface of the micro-mechanical oscillator preform with the micro-machining laser; and
f2) determining a location of a center of the calibration mark in the alignment image;
f3) using the location of the center of the calibration mark in the alignment image and the image coordinate system defined in step (d) to determine the initial coordinates of the beam spot of the micro-machining laser in the image coordinate system.

27. The method according to claim 26, wherein step (d) includes the steps of:
d1) ablating a second calibration mark in the alignment section of the top surface of the micro-mechanical oscillator preform with the micro-machining laser, the second calibration mark located such that centers of the two calibration marks are a predetermined distance apart;
d2) determining the constant distance based on a number of pixels between the centers of the two calibration marks in the alignment image; and
d3) using locations of the two calibration marks in the alignment image and the constant distance determined in step (d2) to define the image coordinate system for the top surface of the micro-mechanical oscillator preform.

28. The method according to claim 26, wherein:
the constant distance is a predetermined distance; and
step (d) includes using the location of the center of the calibration mark in the alignment image, the matrix of pixels, and the constant distance to define the image coordinate system for the top surface of the micro-mechanical oscillator preform.

29. The method according to claim 26, wherein:
the micro-mechanical oscillator preform includes two reference marks, located such that the two reference marks have respective centers that are a predetermined distance apart; and
step (d) includes the steps of;
d1) determining the constant distance based on a number of pixels between the centers of the two reference marks in the alignment image; and
d2) using the location of the center of the calibration mark in the alignment image determined in step (f2) and the constant distance determined in step (d1) to define the image coordinate system for the top surface of the micro-mechanical oscillator preform.

30. The method according to claim 26, wherein:
the submicron feature of the micro-mechanical oscillator preform is formed of the device material, which has a device machining threshold;
the alignment section of the top surface of the micro-mechanical oscillator preform is coated with a coating material having a coating ablation threshold, the coating ablation threshold being less than the device machining threshold;
step (f1) includes operating the micro-machining laser with an alignment peak fluence to ablate the calibration mark in only the coating material of the alignment section, the alignment peak fluence being less than the device machining threshold and greater than the coating ablation threshold; and
step (h) includes operating the micro-machining laser with a machining peak fluence to machine the at least one fine feature in the device material of the submicron feature, the machining peak fluence being greater than the device machining threshold.

31. The method according to claim 25, wherein:
a light beam of the micro-machining laser propagates along a beam path including;
a transversely moveable pinhole mask having a pinhole located in the beam path; and
reducing optics to produce the beam spot on the top surface of the micro-mechanical oscillator preform having a beam spot diameter smaller than a pinhole diameter of the pinhole; and
step (g) includes aligning the beam spot of the micro-machining laser over the portion of the submicron feature of the micro-mechanical oscillator preform by moving the transversely moveable pinhole mask a scaled amount based on a ratio of the pinhole diameter to the beam spot diameter.

32. The method according to claim 25, wherein step (g) includes aligning the beam spot of the micro-machining laser over the portion of the submicron feature of the micro-mechanical oscillator preform by moving the micro-mechanical oscillator preform.

33. The method according to claim 25, wherein the micro-machining laser is one of an ultrafast laser or an excimer laser.

34. The method according to claim 25, wherein a resonance spectrum of the micro-mechanical oscillator is tuned by the at least one fine feature machined on the submicron feature.

35. The method according to claim 34, wherein:
step (a) includes the steps of;
a1) activating the micro-mechanical oscillator;
a2) determining an initial resonance spectrum of the micro-mechanical oscillator;
a3) comparing the initial resonance spectrum determined in step (a2) to a predetermined resonance spectrum; and
a4) determining a desired shape on the submicron feature of the at least one fine feature based on the comparison in step (a3); and
step (h) includes machining the at least one fine feature to have the desired shape on the submicron feature determined in step (a4) with the micro-machining laser.

36. The method according to claim 25, wherein:
the micro-machining laser is an ultrafast laser;
a full width at half maximum (FWHM) of the beam spot of the micro-machining laser on the top surface is diffraction limited; and
step (h) includes operating the micro-machining laser with a machining fluence to machine the at least one fine feature in the device material of the submicron feature, the machining fluence being such that a diameter of an area of the top surface machined by a pulse of the ultrafast laser is less than the FWHM of the beam spot.

37. The method according to claim 25, wherein machining the device material in step (h) includes one of ablating the device material or permanently altering a structure of the device material.

38. A method for manufacturing a mold for microstructures, which includes at least one fine feature on a submicron feature, the at least one fine feature to be located on the submicron feature with a tolerance less than an illumination wavelength used to image the mold during manufacture, the method comprising the steps of:
a) providing a mold preform including the submicron feature on a top surface;
b) illuminating the top surface of the mold preform with light having the illumination wavelength;
c) imaging the top surface of the mold preform with a digital camera to produce an alignment image of the top surface which includes a matrix of pixels, the alignment image being scaled such that each pixel has a width corresponding to a constant distance on the top surface of the mold preform, the constant distance being less than half of the illumination wavelength;
d) defining an image coordinate system for the top surface of the mold preform using the alignment image and the constant distance;
e) determining coordinates of a reference point and an orientation of the submicron feature of the top surface of the mold preform in the image coordinate system using the alignment image;
f) determining initial coordinates of a beam spot of a micro-machining laser in the image coordinate system using the alignment image;
g) aligning the beam spot of the micro-machining laser over a portion of the submicron feature of the mold preform using the coordinates of the reference point and the orientation of the submicron feature determined in step (e) and the initial coordinates of the beam spot determined in step (f); and
h) ablating mold material of the mold preform with the micro-machining laser to form the at least one fine feature on the submicron feature, completing the mold.

39. The method according to claim 38, wherein the microstructures to be formed by the mold are at least one of quantum cellular automata, coupled quantum dot devices, resonant tunneling devices, multifunction optical arrays, diffractive optical elements, beam shapers, microlens arrays, optical diffusers, beam splitters, laser diode correctors, fine pitch gratings, photonic crystals, micro-electrical-mechanical systems, micro-circuitry, polymerase chain reaction microsystems, biochips for detection of hazardous chemical and biological agents, high-throughput drug screening and selection microsystems, micro-surface-acoustic-wave devices, or micro-mechanical oscillators.

40. The method according to claim 38, wherein step (f) includes the steps of:
f1) ablating a calibration mark in an alignment section of the top surface of the mold preform with the micro-machining laser; and
f2) determining a location of a center of the calibration mark in the alignment image;
f3) using the location of the center of the calibration mark in the alignment image and the image coordinate system defined in step (d) to determine the initial coordinates of the beam spot of the micro-machining laser in the image coordinate system.

41. The method according to claim 40, wherein step (d) includes the steps of:
d1) ablating a second calibration mark in the alignment section of the top surface of the mold preform with the micro-machining laser, the second calibration mark located such that centers of the two calibration marks are a predetermined distance apart;
d2) determining the constant distance based on a number of pixels between the centers of the two calibration marks in the alignment image; and
d3) using locations of the two calibration marks in the alignment image and the constant distance determined in step (d2) to define the image coordinate system for the top surface of the mold preform.

42. The method according to claim 40, wherein:
the constant distance is a predetermined distance; and
step (d) includes using the location of the center of the calibration mark in the alignment image, the matrix of pixels, and the constant distance to define the image coordinate system for the top surface of the mold preform.

43. The method according to claim 40, wherein:
the mold preform includes two reference marks, located such that the two reference marks have respective centers that are a predetermined distance apart; and
step (d) includes the steps of;
d1) determining the constant distance based on a number of pixels between the centers of the two reference marks in the alignment image; and
d2) using the location of the center of the calibration mark in the alignment image determined in step (f2) and the constant distance determined in step (d1) to define the image coordinate system for the top surface of the mold preform.

44. The method according to claim 40, wherein:
the submicron feature of the mold preform is formed of the mold material, which has a mold ablation threshold;
the alignment section of the top surface of the mold preform is coated with a coating material having a coating ablation threshold, the coating ablation threshold being less than the mold ablation threshold;
step (f1) includes operating the micro-machining laser with an alignment peak fluence to ablate the calibration mark in only the coating material of the alignment section, the alignment peak fluence being less than the mold ablation threshold and greater than the coating ablation threshold; and
step (h) includes operating the micro-machining laser with an ablation peak fluence to ablate the at least one fine feature in the mold material of the submicron feature, the ablation peak fluence being greater than the mold ablation threshold.

45. The method according to claim 38, wherein:
a light beam of the micro-machining laser propagates along a beam path including;
a transversely moveable pinhole mask having a pinhole located in the beam path; and
reducing optics to produce the beam spot on the top surface of the mold preform having a beam spot diameter smaller than a pinhole diameter of the pinhole; and
step (g) includes aligning the beam spot of the micro-machining laser over the portion of the submicron feature of the mold preform by moving the transversely moveable pinhole mask a scaled amount based on a ratio of the pinhole diameter to the beam spot diameter.

46. The method according to claim 38, wherein step (g) includes aligning the beam spot of the micro-machining laser over the portion of the submicron feature of the mold preform by moving the mold preform.

47. The method according to claim 38, wherein the micro-machining laser is one of an ultrafast laser or an excimer laser.

48. The method according to claim 38, wherein:
the micro-machining laser is an ultrafast laser;
a full width at half maximum (FWHM) of the beam spot of the micro-machining laser on the top surface is diffraction limited; and
step (h) includes operating the micro-machining laser with an ablation fluence to ablate the at least one fine feature in the mold material of the submicron feature, the ablation fluence being such that a diameter of an area of the top surface ablated by a pulse of the ultrafast laser is less than the FWHM of the beam spot.

49. A method for forming a defect in a photonic crystal, the method comprising the steps of:
a) providing a photonic crystal work piece having a top surface including;
an alignment section; and
a photonic crystal section formed of a plurality of air holes in an interstitial material, each air hole having a diameter less than an illumination wavelength used to image the work piece during defect formation and centers of two of the plurality of air holes being a predetermined distance apart;
b) ablating an origin mark in the alignment section of the photonic crystal work piece with a micro-machining laser;
c) illuminating the top surface of the photonic crystal work piece with light having the illumination wavelength;
d) imaging the top surface of the photonic crystal work piece with a digital camera to produce an alignment image of the top surface which includes a matrix of pixels, the alignment image being scaled such that each pixel has a width corresponding to a constant distance on the top surface of the photonic crystal work piece, the constant distance being less than half of the illumination wavelength;
e) determining the constant distance based on a number of pixels in the alignment image between the centers of the two air holes that are separated by the predetermined distance;
f) determining a location of a center of the calibration mark in the alignment image and defining an image coordinate system for the top surface of the photonic crystal work piece using the location of the origin mark in the alignment image, the matrix of pixels, and the constant distance determined in step (e);
g) determining coordinates of centers of the plurality of air holes of the photonic crystal section of the top surface of the photonic crystal work piece in the image coordinate system using the alignment image;
h) determining initial coordinates of a beam spot of the micro-machining laser in the image coordinate system using the location of the origin mark in the alignment image;
i) aligning the beam spot of the micro-machining laser over a defect location of the photonic crystal section using the coordinates of the air holes determined in step (g) and the initial coordinates of the beam spot determined in step (h); and
j) machining interstitial material at the defect location of the photonic crystal section with the micro-machining laser to form the defect.

50. The method according to claim 49, wherein:
the interstitial material has a work piece machining threshold;
the alignment section of the top surface of the photonic crystal work piece is coated with a coating material having a coating ablation threshold, the coating ablation threshold being less than the work piece machining threshold;
step (b) operating the micro-machining laser with an alignment peak fluence to ablate the origin mark in only the coating material of the alignment section, the alignment peak fluence being less than the work piece machining threshold and greater than the coating ablation threshold; and
step (j) includes operating the micro-machining laser with a machining peak fluence to machine the interstitial material at the defect location, the machining peak fluence being greater than the work piece machining threshold.

51. The method according to claim 49, wherein:
a light beam of the micro-machining laser propagates along a beam path including;
a transversely moveable pinhole mask having a pinhole located in the beam path; and
reducing optics to produce the beam spot on the top surface of the photonic crystal work piece having a beam spot diameter smaller than a pinhole diameter of the pinhole; and
step (i) includes aligning the beam spot of the micro-machining laser over the defect location of the photonic crystal section of the photonic crystal work piece by moving the transversely moveable pinhole mask a scaled amount based on a ratio of the pinhole diameter to the beam spot diameter.

52. The method according to claim 49, wherein step (i) includes aligning the beam spot of the micro-machining laser over the defect location of the photonic crystal section of the photonic crystal work piece by moving the photonic crystal work piece.

53. The method according to claim 49, wherein the micro-machining laser is one of an ultrafast laser or an excimer laser.

54. The method according to claim 49, wherein a transmission spectrum of the photonic crystal is tuned by the defect formed in step (j).

55. The method according to claim 54, wherein:
step (a) includes the steps of;
a1) determining the transmission spectrum of the photonic crystal;
a2) comparing the transmission spectrum determined in step (a1) to a predetermined transmission spectrum; and
a3) determining a shape of the defect and the defect location based on the comparison in step (a2); and
step (j) includes forming the defect at the defect location and having the shape determined in step (a3).

56. The method according to claim 49, wherein:
the micro-machining laser is an ultrafast laser;
a full width at half maximum (FWHM) of the beam spot of the micro-machining laser on the top surface is diffraction limited; and
step (j) includes operating the micro-machining laser with a machining fluence to machine the at least one fine feature in the interstitial material of the photonic crystal work piece, the machining fluence being such that a diameter of an area of the top surface machined by a pulse of the ultrafast laser is less than the FWHM of the beam spot.

57. The method according to claim 49, wherein machining the interstitial material in step (j) includes one of ablating the interstitial material or permanently altering a refractive index of the interstitial material.

58. A method for mass customizing a plurality of microstructures with a laser micro-machining system, each microstructure having at least one of a plurality of customization features, the method comprising the steps of:
a) providing a plurality of microstructure preforms, each microstructure preform including a top surface and a submicron feature on the top surface;
b) selecting a microstructure preform from the plurality of microstructure preforms and at least one customization feature from the plurality of customization features, the at least one customization feature to be located on the submicron feature with a tolerance less than an illumination wavelength used to image the microstructures during customization;
c) coarsely aligning the selected microstructure preform in the laser micro-machining system;
d) illuminating the top surface of the selected microstructure preform with light having the illumination wavelength;
e) imaging the top surface of the selected microstructure preform with a digital camera to produce an alignment image of the top surface which includes a matrix of pixels, the alignment image being scaled such that each pixel has a width corresponding to a constant distance on the top surface of the selected microstructure preform, the constant distance being less than half of the illumination wavelength;
f) defining an image coordinate system for the top surface of the selected microstructure preform using the alignment image and the constant distance;
g) determining coordinates of a reference point and an orientation of the submicron feature of the top surface of the selected microstructure preform in the image coordinate system using the alignment image;
h) determining initial coordinates of a beam spot of the laser micro-machining system in the image coordinate system using the alignment image;
i) aligning the beam spot of the laser micro-machining system over a portion of the submicron feature of the selected microstructure preform using the coordinates of the reference point and the orientation of the submicron feature determined in step (g), the initial coordinates of the beam spot determined in step (h), and the at least one customization feature selected in step (b);
j) machining device material of the selected microstructure preform with the laser micro-machining system to form the at least one customization feature selected in step (b) on the submicron feature of the selected microstructure preform to form a customized microstructure; and
k) repeating steps (b), (c), (d), (e), (f), (g), (h), (i), and (j) for each of the plurality of microstructure preforms provided in step (a).

59. The method according to claim 58, wherein the plurality of microstructures to be mass customized are at least one of microstructure molds, quantum cellular automata, coupled quantum dot devices, resonant tunneling devices, multifunction optical arrays, diffractive optical elements, beam shapers, microlens arrays, optical diffusers, beam splitters, laser diode correctors, fine pitch gratings, photonic crystals, micro-electrical-mechanical systems, micro-circuitry, micro-surface-acoustic-wave devices, or micro-mechanical oscillators.

60. The method according to claim 58, wherein step (h) includes the steps of:
h1) ablating a calibration mark in an alignment section of the top surface of the selected microstructure preform with the micro-machining laser; and
h2) determining a location of a center of the calibration mark in the alignment image;
h3) using the location of the center of the calibration mark in the alignment image and the image coordinate system defined in step (f) to determine the initial coordinates of the beam spot of the laser micro-machining system in the image coordinate system.

61. The method according to claim 60, wherein step (f) includes the steps of:
f1) ablating a second calibration mark in the alignment section of the top surface of the selected microstructure preform with the micro-machining laser, the second calibration mark located such that centers of the two calibration marks are a predetermined distance apart;
f2) determining the constant distance based on a number of pixels between the centers of the two calibration marks in the alignment image; and
f3) using locations of the two calibration marks in the alignment image and the constant distance determined in step (f2) to define the image coordinate system for the top surface of the selected microstructure preform.

62. The method according to claim 60, wherein:
the constant distance is a predetermined distance; and
step (f) includes using the location of the center of the calibration mark in the alignment image, the matrix of pixels, and the constant distance to define the image coordinate system for the top surface of the selected microstructure preform.

63. The method according to claim 60, wherein:
the selected microstructure preform includes two reference marks, located such that the two reference marks have respective centers that are a predetermined distance apart; and
step (f) includes the steps of;
f1) determining the constant distance based on a number of pixels between the centers of the two reference marks in the alignment image; and
f2) using the location of the center of the calibration mark in the alignment image determined in step (h2) and the constant distance determined in step (f1) to define the image coordinate system for the top surface of the selected microstructure preform.

64. The method according to claim 60, wherein:
the submicron features of the plurality of microstructure preforms are formed of the device material, which has a device machining threshold;
the alignment sections of the top surfaces of the plurality of microstructure preforms are coated with a coating material having a coating ablation threshold, the coating ablation threshold being less than the device machining threshold;
step (h1) includes operating the micro-machining laser with an alignment peak fluence to ablate the calibration mark in only the coating material of the alignment section, the alignment peak fluence being less than the device machining threshold and greater than the coating ablation threshold; and
step (j) includes operating the micro-machining laser with a machining peak fluence to machine the at least one fine feature selected in step (b) in the device material of the submicron feature of the selected microstructure preform, the machining peak fluence being greater than the device machining threshold.

65. The method according to claim 58, wherein:
a light beam of the micro-machining laser propagates along a beam path including;
a transversely moveable pinhole mask having a pinhole located in the beam path; and
reducing optics to produce the beam spot on the top surface of the selected microstructure preform having a beam spot diameter smaller than a pinhole diameter of the pinhole; and
step (i) includes aligning the beam spot of the laser micro-machining system over the portion of the submicron feature of the selected microstructure preform by moving the transversely moveable pinhole mask a scaled amount based on a ratio of the pinhole diameter to the beam spot diameter.

66. The method according to claim 58, wherein step (i) includes aligning the beam spot of the laser micro-machining system over the portion of the submicron feature of the selected microstructure preform by moving the selected microstructure preform.

67. The method according to claim 58, wherein a micro-machining laser of the laser micro-machining system is one of an ultrafast laser or an excimer laser.

68. The method according to claim 58, wherein:
a micro-machining laser of the laser micro-machining system is an ultrafast laser;
a full width at half maximum (FWHM) of the beam spot of the micro-machining laser on the top surface is diffraction limited; and
step (j) includes operating the micro-machining laser with a machining fluence to machine the at least one fine feature in the device material of the submicron feature, the machining fluence being such that a diameter of an area of the top surface machined by a pulse of the ultrafast laser is less than the FWHM of the beam spot.

69. The method according to claim 58, wherein machining the device material in step (j) includes one of ablating the device material or permanently altering a structure of the device material.

70. A method for repairing a microstructure with a laser micro-machining system, the microstructure including a submicron defect on a top surface, such that machining of the submicron defect is performed with an accuracy of less than an illumination wavelength used to image the microstructure during repair, the method comprising the steps of:
a) coupling the defective microstructure to a repair mount, the repair mount including an alignment surface adjacent to the defective microstructure;
b) coarsely aligning the repair mount in the laser micro-machining system, such that a beam spot of a micro-machining laser of the laser micro-machining system is incident on the alignment surface of the repair mount;
c) ablating a calibration mark in the alignment surface of repair mount with the micro-machining laser;
d) illuminating the top surface of the defective microstructure and the alignment surface of the repair mount with light having the illumination wavelength;
e) imaging the top surface of the defective microstructure and the alignment surface of the repair mount with a digital camera to produce an alignment image of the top surface which includes a matrix of pixels, the alignment image being scaled such that each pixel has a width corresponding to a constant distance on the imaged surfaces, the constant distance being less than half of the illumination wavelength;
f) determining a location of a center of the calibration mark in the alignment image and defining an image coordinate system for the imaged surfaces using the alignment image, the location of the center of the calibration mark in the alignment image, and the constant distance;
g) determining coordinates of the submicron defect of the top surface of the defective microstructure in the image coordinate system using the alignment image;
h) using the location of the center of the calibration mark in the alignment image and the image coordinate system defined in step (f) to determine initial coordinates of the beam spot of the micro-machining laser in the image coordinate system;
i) aligning the beam spot of the micro-machining laser over a portion of the submicron defect of the defective microstructure using the coordinates of the submicron defect determined in step (g) and the initial coordinates of the beam spot determined in step (h); and
j) machining device material of the defective microstructure with the micro-machining laser to repair the submicron defect of the defective microstructure.

71. The method according to claim 70, wherein the microstructure to be repaired includes at least one of a microstructure mold, a quantum cellular automaton, a coupled quantum dot device, a resonant tunneling device, a multifunction optical array, a diffractive optical element, a beam shaper, a microlens array, an optical diffuser, a beam splitter, a laser diode corrector, a fine pitch grating, a photonic crystal, a micro-electrical-mechanical system, micro-circuitry, a micro-surface-acoustic-wave device, a micro-mechanical oscillator, a polymerase chain reaction microsystem, a biochip for detection of hazardous chemical and biological agents, or a high-throughput drug screening and selection microsystem.

72. The method according to claim 70, wherein step (f) includes the steps of:
f1) ablating a second calibration mark in the alignment surface of the repair mount with the micro-machining laser, the second calibration mark located such that centers of the two calibration marks are a predetermined distance apart;
f2) determining a location of a center of the second calibration mark in the alignment image;
f3) determining the constant distance based on a number of pixels between the centers of the two calibration marks in the alignment image; and
f4) using the locations of the centers of the two calibration marks in the alignment image and the constant distance determined in step (f3) to define the image coordinate system for the imaged surfaces.

73. The method according to claim 70, wherein:
the constant distance is a predetermined distance; and
step (f) includes using the location of the center of the calibration mark in the alignment image, the matrix of pixels, and the constant distance to define the image coordinate system for the imaged surfaces.

74. The method according to claim 70, wherein:
the defective microstructure includes two reference marks, located such that the two reference marks have respective centers that are a predetermined distance apart; and
step (f) includes the steps of;
f1) determining the constant distance based on a number of pixels between the centers of the two reference marks in the alignment image; and
f2) using the location of the center of the calibration mark in the alignment image and the constant distance determined in step (f1) to define the image coordinate system for the imaged surfaces.

75. The method according to claim 70, wherein:
the submicron defect of the defective microstructure is formed of the device material, which has a device machining threshold;
the alignment surface of the repair mount is formed of an alignment material having an alignment ablation threshold, the alignment ablation threshold being less than the device machining threshold;
step (c) includes operating the micro-machining laser with an alignment peak fluence to ablate the calibration mark in the alignment material of the alignment surface, the alignment peak fluence being less than the device machining threshold and greater than the alignment ablation threshold; and
step (j) includes operating the micro-machining laser with a repair peak fluence to repair the submicron defect in the device material of the defective microstructure, the repair peak fluence being greater than the device machining threshold.

76. The method according to claim 70, wherein:
a light beam of the micro-machining laser propagates along a beam path including;
a transversely moveable pinhole mask having a pinhole located in the beam path; and
reducing optics to produce the beam spot on the top surface of the defective microstructure and the alignment surface of the repair mount having a beam spot diameter smaller than a pinhole diameter of the pinhole; and
step (i) includes aligning the beam spot of the micro-machining laser over the portion of the submicron defect of the defective microstructure by moving the transversely moveable pinhole mask a scaled amount based on a ratio of the pinhole diameter to the beam spot diameter.

77. The method according to claim 70, wherein step (i) includes aligning the beam spot of the micro-machining laser over the portion of the submicron defect of the defective microstructure by moving the repair mount.

78. The method according to claim 70, wherein the micro-machining laser is one of an ultrafast laser or an excimer laser.

79. The method according to claim 70, wherein:
the microstructure to be repaired includes micro-circuitry; and
the submicron defect is a short circuit.

80. The method according to claim 70, wherein:
the micro-machining laser is an ultrafast laser;
a full width at half maximum (FWHM) of the beam spot of the micro-machining laser on the top surface is diffraction limited; and
step (j) includes operating the micro-machining laser with a machining fluence to machine the device material of the submicron defect, the machining fluence being such that a diameter of an area of the top surface machined by a pulse of the ultrafast laser is less than the FWHM of the beam spot.

81. The method according to claim 70, wherein machining the device material in step (j) includes one of ablating the device material or permanently altering a structure of the device material.

82. A method for pre-calibration of a laser micro-machining system to achieve alignment tolerances greater than a diffraction limit of an illumination wavelength used during pre-calibration for machining of pre-existing microstructures including at least one submicron feature, the method comprising the steps of:
a) mounting an alignment blank in the laser micro-machining system, such that a beam spot of a micro-machining laser of the laser micro-machining system is incident on a top surface of the alignment blank;
b) ablating a first calibration mark and a second calibration mark in the top surface of the alignment blank with the micro-machining laser, the two calibration marks located such that centers of the two calibration marks are a predetermined distance apart;
c) illuminating the top surface of the alignment blank with light having the illumination wavelength;
d) imaging the top surface of the alignment blank with a digital camera to produce an alignment image of the top surface which includes a matrix of pixels, the alignment image being scaled such that each pixel has a width corresponding to a constant distance on the imaged surface, the constant distance being less than half of the illumination wavelength;
e) determining the constant distance based on a number of pixels between the centers of the two calibration marks in the alignment image;
f) determining locations of centers of the two calibration marks in the alignment image and using the locations of the centers of the two calibration marks in the alignment image and the constant distance determined in step (e) to define an image coordinate system for surfaces imaged by the digital camera;
g) using the location of the center of the second calibration mark in the alignment image and the image coordinate system defined in step (f) to determine initial coordinates of the beam spot of the micro-machining laser in the image coordinate system;
h) removing the alignment blank from the laser micro-machining system; and
i) mounting one of the pre-existing microstructures to be machined in the laser micro-machining system, such that a beam spot of the micro-machining laser is incident on a machining surface of the one pre-existing microstructure.

83. The method according to claim 82, wherein the pre-existing microstructures to be machined include at least one of a microstructure mold, a quantum cellular automaton, a coupled quantum dot device, a resonant tunneling device, a multifunction optical array, a diffractive optical element, a beam shaper, a microlens array, an optical diffuser, a beam splitter, a laser diode corrector, a fine pitch grating, a photonic crystal, a micro-electrical-mechanical system, micro-circuitry, a micro-surface-acoustic-wave device, a micro-mechanical oscillator, a polymerase chain reaction microsystem, a biochip for detection of hazardous chemical and biological agents, or a high-throughput drug screening and selection microsystem.

84. The method according to claim 82, wherein a light beam of the micro-machining laser propagates along a beam path including:
a transversely moveable pinhole mask having a pinhole located in the beam path; and
reducing optics to produce the beam spot on the surfaces imaged by the digital camera having a beam spot diameter smaller than a pinhole diameter of the pinhole.

85. The method according to claim 82, wherein the micro-machining laser is one of an ultrafast laser or an excimer laser.
